(19) United States
(12) Patent Application Publication
(10) Pub. No.: US 2026/0312719 A1
(43) Pub. Date: Oct. 8, 2026

(54) SHAPING BITS FOR POLAR CODING

(71) Applicant: QUALCOMM Incorporated, San Diego, CA (US)

(72) Inventors: Liangming WU, Beijing (CN); Wei LIU, Beijing (CN); Jian LI, Shanghai (CN); Kirill IVANOV, La Jolla, CA (US); Wei YANG, San Diego, CA (US); Kexin XIAO, Shanghai (CN); Changlong XU, Beijing (CN); Jing JIANG, San Diego, CA (US); Hao XU, Beijing (CN)

(21) Appl. No.: 19/483,358

(22) PCT Filed: Jun. 30, 2023
(86) PCT No.: PCT/CN2023/104701

§ 371 Date: Nov. 11, 2025

(51) Int. Cl. H04L 1/00; H03M 13/13

(52) U.S. Cl. CPC H04L 1/0041; H03M 13/13; H04L 1/0057

(57) ABSTRACT

Various aspects of the present disclosure generally relate to wireless communication. In some aspects, a wireless communication device may encode one or more information bits into a plurality of polar code sub-block outputs, identify one or more shaping bits for a first polar code sub-block output of the plurality of polar code sub-block outputs, and transmit a polar-coded codeword derived from at least the first polar code sub-block output and the second polar code sub-block output. In some aspects, a wireless communication device may identify one or more shaping bit subchannels, identify one or more information bit subchannels, and transmit one or more shaping bits in the one or more shaping bit subchannels and one or more information bits in the one or more information bit subchannels. Numerous other aspects are described.

### FIELD OF THE DISCLOSURE

Aspects of the present disclosure generally relate to wireless communication and to techniques and apparatuses for shaping bits for polar coding.

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, or the like). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless network may include one or more network nodes that support communication for wireless communication devices, such as a user equipment (UE) or multiple UEs. A UE may communicate with a network node via downlink communications and uplink communications. “Downlink” (or “DL”) refers to a communication link from the network node to the UE, and “uplink” (or “UL”) refers to a communication link from the UE to the network node. Some wireless networks may support device-to-device communication, such as via a local link (e.g., a sidelink (SL), a wireless local area network (WLAN) link, and/or a wireless personal area network (WPAN) link, among other examples).

The above multiple access technologies have been adopted in various telecommunication standards to provide a common protocol that enables different UEs to communicate on a municipal, national, regional, and/or global level. New Radio (NR), which may be referred to as 5G, is a set of enhancements to the LTE mobile standard promulgated by the 3GPP. NR is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM and/or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in LTE, NR, and other radio access technologies remain useful.

### SUMMARY

Some aspects described herein relate to a wireless communication device for wireless communication. The wireless communication device may include one or more memories and one or more processors coupled to the one or more memories. The one or more processors may be configured to encode one or more information bits into a plurality of polar code sub-block outputs. The one or more processors may be configured to identify one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits. The one or more processors may be configured to transmit a polar-coded codeword derived from at least the first polar code sub-block output and the second polar code sub-block output.

Some aspects described herein relate to a method of wireless communication performed by a wireless communication device. The method may include encoding one or more information bits into a plurality of polar code sub-block outputs. The method may include identifying one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits. The method may include transmitting a polar-coded codeword derived from at least the first polar code sub-block output and the second polar code sub-block output.

Some aspects described herein relate to a non-transitory computer-readable medium that stores a set of instructions for wireless communication by a wireless communication device. The set of instructions, when executed by one or more processors of the wireless communication device, may cause the wireless communication device to encode one or more information bits into a plurality of polar code sub-block outputs. The set of instructions, when executed by one or more processors of the wireless communication device, may cause the wireless communication device to identify one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits. The set of instructions, when executed by one or more processors of the wireless communication device, may cause the wireless communication device to transmit a polar-coded codeword derived from at least the first polar code sub-block output and the second polar code sub-block output.

Some aspects described herein relate to an apparatus for wireless communication. The apparatus may include means for encoding one or more information bits into a plurality of polar code sub-block outputs. The apparatus may include means for identifying one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits. The apparatus may include means for transmitting a polar-coded codeword derived from at least the first polar code sub-block output and the second polar code sub-block output.

Some aspects described herein relate to a wireless communication device for wireless communication. The wireless communication device may include one or more memories and one or more processors coupled to the one or more memories. The one or more processors may be configured to identify one or more shaping bit subchannels of a mother code sequence, wherein the one or more shaping bit subchannels are associated with a first polar code sub-block output. The one or more processors may be configured to identify one or more information bit subchannels of the mother code sequence. The one or more processors may be configured to transmit one or more shaping bits in the one or more shaping bit subchannels and one or more information bits in the one or more information bit subchannels.

Some aspects described herein relate to a method of wireless communication performed by a wireless communication device. The method may include identifying one or more shaping bit subchannels of a mother code sequence, wherein the one or more shaping bit subchannels are associated with a first polar code sub-block output. The method may include identifying one or more information bit subchannels of the mother code sequence. The method may include transmitting one or more shaping bits in the one or more shaping bit subchannels and one or more information bits in the one or more information bit subchannels.

Some aspects described herein relate to a non-transitory computer-readable medium that stores a set of instructions for wireless communication by a wireless communication device. The set of instructions, when executed by one or more processors of the wireless communication device, may cause the wireless communication device to identify one or more shaping bit subchannels of a mother code sequence, wherein the one or more shaping bit subchannels are associated with a first polar code sub-block output. The set of instructions, when executed by one or more processors of the wireless communication device, may cause the wireless communication device to identify one or more information bit subchannels of the mother code sequence. The set of instructions, when executed by one or more processors of the wireless communication device, may cause the wireless communication device to transmit one or more shaping bits in the one or more shaping bit subchannels and one or more information bits in the one or more information bit subchannels.

Some aspects described herein relate to an apparatus for wireless communication. The apparatus may include means for identifying one or more shaping bit subchannels of a mother code sequence, wherein the one or more shaping bit subchannels are associated with a first polar code sub-block output. The apparatus may include means for identifying one or more information bit subchannels of the mother code sequence. The apparatus may include means for transmitting one or more shaping bits in the one or more shaping bit subchannels and one or more information bits in the one or more information bit subchannels.

Aspects generally include a method, apparatus, system, computer program product, non-transitory computer-readable medium, user equipment, base station, network entity, network node, wireless communication device, and/or processing system as substantially described herein with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example of a wireless network, in accordance with the present disclosure.

FIG. 2 is a diagram illustrating an example of a network node in communication with a user equipment (UE) in a wireless network, in accordance with the present disclosure.

FIG. 3 is a diagram illustrating an example disaggregated base station architecture, in accordance with the present disclosure.

FIG. 4 is a diagram illustrating an example of a transmitter configured for separate coding and probabilistic amplitude shaping (PAS) operations, in accordance with the present disclosure.

FIG. 5 is a diagram illustrating an example associated with coding and modulation operations for control channels for joint coding and shaping, in accordance with the present disclosure.

FIG. 6 is a diagram illustrating an example associated with polar precoding and transformation for joint coding and shaping, in accordance with the present disclosure.

FIG. 7 is a diagram that demonstrates how certain examples associated with joint coding and shaping can involve excessive transmit power, in accordance with the present disclosure.

FIG. 8 is a diagram illustrating an example associated with identifying shaping bits for a polar-coded codeword, in accordance with the present disclosure.

FIG. 9 is a diagram illustrating an example associated with power reduction associated with identifying shaping bits for a polar-coded codeword, in accordance with the present disclosure.

FIG. 10 is a diagram illustrating an example associated with bits of a polar code sub-block output that are independent from shaping bits, in accordance with the present disclosure.

FIG. 11 is a diagram illustrating an example associated with index reliabilities, in accordance with the present disclosure.

FIG. 12 is a diagram illustrating an example associated with a channel code shaper that utilizes block code for shaping via a log-likelihood ratio (LLR) generator, in accordance with the present disclosure.

FIG. 13 is a diagram illustrating an example associated with a structure in which information bits, frozen bits, and shaping bits are assigned to subchannels that are associated with a plurality of polar code sub-block outputs, in accordance with the present disclosure.

FIG. 14 is a diagram illustrating an example associated with calculating shaping bits based on an association of a plurality of polar code sub-block outputs with a punctured node or with a shortened node, in accordance with the present disclosure.

FIG. 15 is a diagram illustrating an example associated with a polar code sub-block output that is associated with a quantity of polarization iterations, in accordance with the present disclosure.

FIG. 16 is a diagram illustrating an example associated with sequence construction for joint coding and shaping with polar codes, in accordance with the present disclosure.

FIG. 17 is a diagram illustrating examples associated with identifying one or more shaping bit subchannels based on reliability metrics, in accordance with the present disclosure.

FIG. 18 is a diagram illustrating an example associated with replacing one or more candidate shaping bit subchannels with one or more shaping bit subchannels, in accordance with the present disclosure.

FIG. 19 is a diagram illustrating an example associated with identifying the one or more information bit subchannels and/or one or more shaping bit subchannels based at least in part on a generated symbol distribution, in accordance with the present disclosure.

FIG. 20 is a diagram illustrating an example process performed, for example, by a wireless communication device, in accordance with the present disclosure.

FIG. 21 is a diagram illustrating an example process performed, for example, by a wireless communication device, in accordance with the present disclosure.

FIG. 22 is a diagram of an example apparatus for wireless communication, in accordance with the present disclosure.

### DETAILED DESCRIPTION

Polar coding is a channel coding scheme used in 5G control channels. Polar coding has a built-in channel polarization structure that splits (or “polarizes”) polar code subchannels into reliable subchannels and unreliable subchannels. The reliable subchannels carry information bits and the unreliable channels carry “frozen” or “fixed” bits (e.g., “0” bits).

Polar coding may involve inputting a mother code sequence of bits into a plurality of polar transforms. The polar transforms may output polar code sub-block outputs that can be input into an XOR gate with each other. For example, the polar code sub-block output that contains shaping bits can be input into a first XOR gate with other polar code sub-block outputs. As a result, the polar code sub-block outputs are not independent from the shaping bits, which can increase the transmit power associated with the polar code sub-block outputs.

Furthermore, placement of the shaping bits and information bits within subchannels may not satisfy a target forward error correction (FEC) performance threshold and/or a target shaping performance threshold. Diminished FEC performance can increase errors associated with the transmission of the shaping bits and/or the information bits. Diminished shaping performance can increase the transmit power of the transmission.

Various aspects relate generally to shaping bits for polar coding. Some aspects more specifically relate to polar code sub-block outputs being independent from shaping bits. In some examples, a wireless communication device (e.g., a transmitter, such as a UE or a network node) may encode one or more information bits into a plurality of polar code sub-block outputs. The wireless communication device may identify one or more shaping bits for a first polar code sub-block output of the plurality of polar code sub-block outputs. The first polar code sub-block output is mapped to a first bit level and a second polar code sub-block output of the plurality of the polar code sub-block outputs is mapped to a second bit level. The second polar code sub-block output may be independent from the one or more shaping bits. The wireless communication device may transmit a polar-coded codeword derived from at least the first polar code sub-block output and the second polar code sub-block output.

In some examples, the polar-coded codeword is based at least in part on a Gray mapping, and the first polar code sub-block output does not map to any sign bits. In some examples, the polar-coded codeword is based at least in part on a natural order mapping, and the first polar code sub-block output may be mapped to one or more sign bits.

Some aspects relate to identifying shaping bit subchannels and information bit subchannels of a mother code sequence. In some examples, the wireless communication device may identify one or more shaping bit subchannels of a mother code sequence. The one or more shaping bit subchannels are associated with a first polar code sub-block output. The wireless communication device may identify one or more information bit subchannels of the mother code sequence. The wireless communication device may transmit one or more shaping bits in the one or more shaping bit subchannels and one or more information bits in the one or more information bit subchannels.

In a first aspect, identifying the one or more shaping bit subchannels includes identifying the one or more shaping bit subchannels based at least in part on first reliability metrics of subchannels associated with at least the first polar code sub-block output and second reliability metrics of subchannels associated with at least a second polar code sub-block. In a second aspect, identifying the one or more shaping bit subchannels includes identifying the one or more shaping bit subchannels based at least in part on first reliability metrics of subchannels associated with the first polar code sub-block output independent of any second reliability metric of subchannels associated with any second polar code sub-block output. In a third aspect, identifying the one or more shaping bit subchannels may include a combination of identifying the one or more shaping bit subchannels based at least in part on first reliability metrics of subchannels associated with at least the first polar code sub-block output and second reliability metrics of subchannels associated with at least a second polar code sub-block output and identifying the one or more shaping bit subchannels based at least in part on the first reliability metrics independent of the second reliability metrics.

Particular aspects of the subject matter described in this disclosure can be implemented to realize one or more of the following potential advantages. In some examples, the second polar code sub-block output being independent from the one or more shaping bits may enable the wireless communication device to reduce the transmit power. The second polar code sub-block output being independent from the one or more shaping bits may enable the second polar code sub-block output to be predetermined or fixed such that the shaping bits do not change the value of the second polar code sub-block output.

Basing the polar-coded codeword at least in part on the Gray mapping and not mapping the first polar code sub-block output to any sign bits may enable the techniques described herein to be compatible with Gray mapping techniques. Basing the polar-coded codeword at least in part on the natural order mapping and mapping the first polar code sub-block output to one or more sign bits may enable the techniques described herein to be compatible with natural order mapping techniques.

In some examples, identifying the shaping bit subchannels and/or the information bit subchannels may enable the wireless communication device to control the FEC performance and/or shaping performance of the corresponding transmission. For example, the wireless communication device may assign shaping bits to shaping bit subchannels and information bits to information bit subchannels based on a target FEC performance threshold and/or a target shaping performance threshold. Thus, the wireless communication device may achieve a target balance between FEC performance and shaping performance. The first aspect may improve FEC protection, and the second aspect may improve shaping performance. The third aspect may enable the wireless communication device to balance a target FEC performance with a target shaping performance.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, algorithms, or the like (collectively referred to as “elements”). These elements may be implemented using hardware, software, or combinations thereof. Whether such elements are implemented as hardware or software depends upon the particular application and design constraints imposed on the overall system.

While aspects may be described herein using terminology commonly associated with a 5G or New Radio (NR) radio access technology (RAT), aspects of the present disclosure can be applied to other RATs, such as a 3G RAT, a 4G RAT, and/or a RAT subsequent to 5G (e.g., 6G).

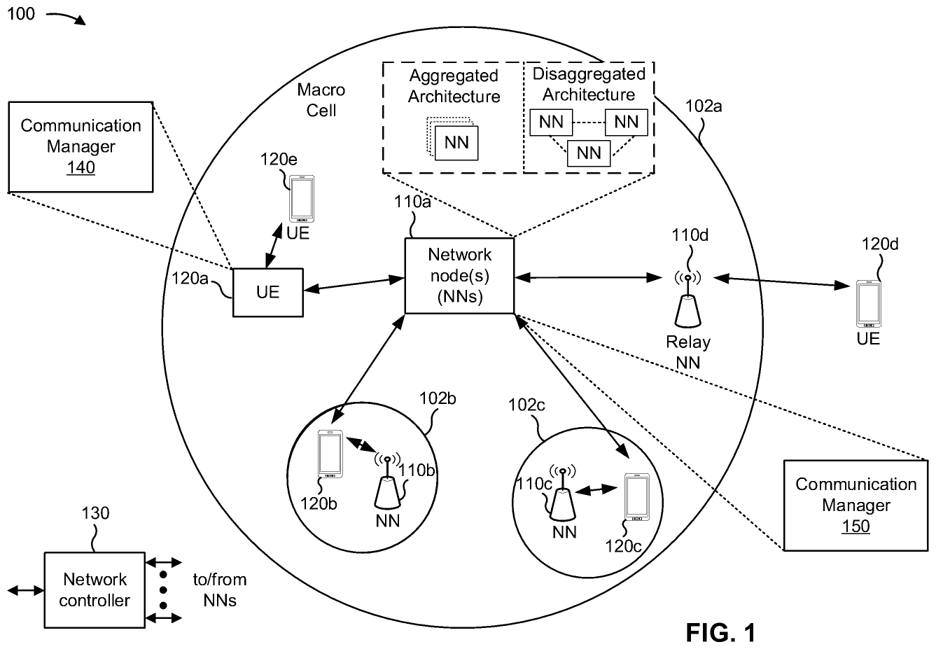

FIG. 1 is a diagram illustrating an example of a wireless network 100, in accordance with the present disclosure. The wireless network 100 may be or may include elements of a 5G (e.g., NR) network and/or a 4G (e.g., Long Term Evolution (LTE)) network, among other examples. The wireless network 100 may include one or more network nodes 110 (shown as a network node 110a, a network node 110b, a network node 110c, and a network node 110d), a user equipment (UE) 120 or multiple UEs 120 (shown as a UE 120a, a UE 120b, a UE 120c, a UE 120d, and a UE 120e), and/or other entities. A network node 110 is a network node that communicates with UEs 120. As shown, a network node 110 may include one or more network nodes. For example, a network node 110 may be an aggregated network node, meaning that the aggregated network node is configured to utilize a radio protocol stack that is physically or logically integrated within a single radio access network (RAN) node (e.g., within a single device or unit). As another example, a network node 110 may be a disaggregated network node (sometimes referred to as a disaggregated base station), meaning that the network node 110 is configured to utilize a protocol stack that is physically or logically distributed among two or more nodes (such as one or more central units (CUs), one or more distributed units (DUs), or one or more radio units (RUs)).

In some examples, a network node 110 is or includes a network node that communicates with UEs 120 via a radio access link, such as an RU. In some examples, a network node 110 is or includes a network node that communicates with other network nodes 110 via a fronthaul link or a midhaul link, such as a DU. In some examples, a network node 110 is or includes a network node that communicates with other network nodes 110 via a midhaul link or a core network via a backhaul link, such as a CU. In some examples, a network node 110 (such as an aggregated network node 110 or a disaggregated network node 110) may include multiple network nodes, such as one or more RUs, one or more CUs, and/or one or more DUs. A network node 110 may include, for example, an NR base station, an LTE base station, a Node B, an eNB (e.g., in 4G), a gNB (e.g., in 5G), an access point, a transmission reception point (TRP), a DU, an RU, a CU, a mobility element of a network, a core network node, a network element, a network equipment, a RAN node, or a combination thereof. In some examples, the network nodes 110 may be interconnected to one another or to one or more other network nodes 110 in the wireless network 100 through various types of fronthaul, midhaul, and/or backhaul interfaces, such as a direct physical connection, an air interface, or a virtual network, using any suitable transport network.

In some examples, a network node 110 may provide communication coverage for a particular geographic area. In the Third Generation Partnership Project (3GPP), the term “cell” can refer to a coverage area of a network node 110 and/or a network node subsystem serving this coverage area, depending on the context in which the term is used. A network node 110 may provide communication coverage for a macro cell, a pico cell, a femto cell, and/or another type of cell. A macro cell may cover a relatively large geographic area (e.g., several kilometers in radius) and may allow unrestricted access by UEs 120 with service subscriptions. A pico cell may cover a relatively small geographic area and may allow unrestricted access by UEs 120 with service subscriptions. A femto cell may cover a relatively small geographic area (e.g., a home) and may allow restricted access by UEs 120 having association with the femto cell (e.g., UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node. In the example shown in FIG. 1, the network node 110a may be a macro network node for a macro cell 102a, the network node 110b may be a pico network node for a pico cell 102b, and the network node 110c may be a femto network node for a femto cell 102c. A network node may support one or multiple (e.g., three) cells. In some examples, a cell may not necessarily be stationary, and the geographic area of the cell may move according to the location of a network node 110 that is mobile (e.g., a mobile network node).

In some aspects, the terms “base station” or “network node” may refer to an aggregated base station, a disaggregated base station, an integrated access and backhaul (IAB) node, a relay node, or one or more components thereof. For example, in some aspects, “base station” or “network node” may refer to a CU, a DU, an RU, a Near-Real Time (Near-RT) RAN Intelligent Controller (RIC), or a Non-Real Time (Non-RT) RIC, or a combination thereof. In some aspects, the terms “base station” or “network node” may refer to one device configured to perform one or more functions, such as those described herein in connection with the network node 110. In some aspects, the terms “base station” or “network node” may refer to a plurality of devices configured to perform the one or more functions. For example, in some distributed systems, each of a quantity of different devices (which may be located in the same geographic location or in different geographic locations) may be configured to perform at least a portion of a function, or to duplicate performance of at least a portion of the function, and the terms “base station” or “network node” may refer to any one or more of those different devices. In some aspects, the terms “base station” or “network node” may refer to one or more virtual base stations or one or more virtual base station functions. For example, in some aspects, two or more base station functions may be instantiated on a single device. In some aspects, the terms “base station” or “network node” may refer to one of the base station functions and not another. In this way, a single device may include more than one base station.

The wireless network 100 may include one or more relay stations. A relay station is a network node that can receive a transmission of data from an upstream node (e.g., a network node 110 or a UE 120) and send a transmission of the data to a downstream node (e.g., a UE 120 or a network node 110). A relay station may be a UE 120 that can relay transmissions for other UEs 120. In the example shown in FIG. 1, the network node 110d (e.g., a relay network node) may communicate with the network node 110a (e.g., a macro network node) and the UE 120d in order to facilitate communication between the network node 110a and the UE 120d. A network node 110 that relays communications may be referred to as a relay station, a relay base station, a relay network node, a relay node, a relay, or the like.

The wireless network 100 may be a heterogeneous network that includes network nodes 110 of different types, such as macro network nodes, pico network nodes, femto network nodes, relay network nodes, or the like. These different types of network nodes 110 may have different transmit power levels, different coverage areas, and/or different impacts on interference in the wireless network 100. For example, macro network nodes may have a high transmit power level (e.g., 5 to 40 watts) whereas pico network nodes, femto network nodes, and relay network nodes may have lower transmit power levels (e.g., 0.1 to 2 watts).

A network controller 130 may couple to or communicate with a set of network nodes 110 and may provide coordination and control for these network nodes 110. The network controller 130 may communicate with the network nodes 110 via a backhaul communication link or a midhaul communication link. The network nodes 110 may communicate with one another directly or indirectly via a wireless or wireline backhaul communication link. In some aspects, the network controller 130 may be a CU or a core network device, or may include a CU or a core network device.

The UEs 120 may be dispersed throughout the wireless network 100, and each UE 120 may be stationary or mobile. A UE 120 may include, for example, an access terminal, a terminal, a mobile station, and/or a subscriber unit. A UE 120 may be a cellular phone (e.g., a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (e.g., a smart watch, smart clothing, smart glasses, a smart wristband, smart jewelry (e.g., a smart ring or a smart bracelet)), an entertainment device (e.g., a music device, a video device, and/or a satellite radio), a vehicular component or sensor, a smart meter/sensor, industrial manufacturing equipment, a global positioning system device, a UE function of a network node, and/or any other suitable device that is configured to communicate via a wireless or wired medium.

Some UEs 120 may be considered machine-type communication (MTC) or evolved or enhanced machine-type communication (eMTC) UEs. An MTC UE and/or an eMTC UE may include, for example, a robot, an unmanned aerial vehicle, a remote device, a sensor, a meter, a monitor, and/or a location tag, that may communicate with a network node, another device (e.g., a remote device), or some other entity. Some UEs 120 may be considered Internet-of-Things (IoT) devices, and/or may be implemented as NB-IoT (narrowband IoT) devices. Some UEs 120 may be considered a Customer Premises Equipment. A UE 120 may be included inside a housing that houses components of the UE 120, such as processor components and/or memory components. In some examples, the processor components and the memory components may be coupled together. For example, the processor components (e.g., one or more processors) and the memory components (e.g., a memory) may be operatively coupled, communicatively coupled, electronically coupled, and/or electrically coupled.

In general, any number of wireless networks 100 may be deployed in a given geographic area. Each wireless network 100 may support a particular RAT and may operate on one or more frequencies. A RAT may be referred to as a radio technology, an air interface, or the like. A frequency may be referred to as a carrier, a frequency channel, or the like. Each frequency may support a single RAT in a given geographic area in order to avoid interference between wireless networks of different RATs. In some cases, NR or 5G RAT networks may be deployed.

In some examples, two or more UEs 120 (e.g., shown as UE 120a and UE 120e) may communicate directly using one or more sidelink channels (e.g., without using a network node 110 as an intermediary to communicate with one another). For example, the UEs 120 may communicate using peer-to-peer (P2P) communications, device-to-device (D2D) communications, a vehicle-to-everything (V2X) protocol (e.g., which may include a vehicle-to-vehicle (V2V) protocol, a vehicle-to-infrastructure (V2I) protocol, or a vehicle-to-pedestrian (V2P) protocol), and/or a mesh network. In such examples, a UE 120 may perform scheduling operations, resource selection operations, and/or other operations described elsewhere herein as being performed by the network node 110.

Devices of the wireless network 100 may communicate using the electromagnetic spectrum, which may be subdivided by frequency or wavelength into various classes, bands, channels, or the like. For example, devices of the wireless network 100 may communicate using one or more operating bands. In 5G NR, two initial operating bands have been identified as frequency range designations FR1 (410 MHz-7.125 GHz) and FR2 (24.25 GHz-52.6 GHz). It should be understood that although a portion of FR1 is greater than 6 GHZ, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHz-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHz), and FR5 (114.25 GHZ-300 GHz). Each of these higher frequency bands falls within the EHF band.

With the above examples in mind, unless specifically stated otherwise, it should be understood that the term “sub-6 GHz” or the like, if used herein, may broadly represent frequencies that may be less than 6 GHZ, may be within FR1, or may include mid-band frequencies. Further, unless specifically stated otherwise, it should be understood that the term “millimeter wave” or the like, if used herein, may broadly represent frequencies that may include mid-band frequencies, may be within FR2, FR4, FR4-a or FR4-1, and/or FR5, or may be within the EHF band. It is contemplated that the frequencies included in these operating bands (e.g., FR1, FR2, FR3, FR4, FR4-a, FR4-1, and/or FR5) may be modified, and techniques described herein are applicable to those modified frequency ranges.

In some aspects, the UE 120 may include a communication manager 140. As described in more detail elsewhere herein, the communication manager 140 may encode one or more information bits into a plurality of polar code sub-block outputs; identify one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits; and transmit a polar-coded codeword derived from at least the first polar code sub-block output and the second polar code sub-block output.

In some aspects, the communication manager 140 may identify one or more shaping bit subchannels of a mother code sequence, wherein the one or more shaping bit subchannels are associated with a first polar code sub-block output; identify one or more information bit subchannels of the mother code sequence; and transmit one or more shaping bits in the one or more shaping bit subchannels and one or more information bits in the one or more information bit subchannels. Additionally, or alternatively, the communication manager 140 may perform one or more other operations described herein.

In some aspects, the network node 110 may include a communication manager 150. As described in more detail elsewhere herein, the communication manager 150 may encode one or more information bits into a plurality of polar code sub-block outputs; identify one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits; and transmit a polar-coded codeword derived from at least the first polar code sub-block output and the second polar code sub-block output.

In some aspects, the communication manager 150 may identify one or more shaping bit subchannels of a mother code sequence, wherein the one or more shaping bit subchannels are associated with a first polar code sub-block output; identify one or more information bit subchannels of the mother code sequence; and transmit one or more shaping bits in the one or more shaping bit subchannels and one or more information bits in the one or more information bit subchannels. Additionally, or alternatively, the communication manager 150 may perform one or more other operations described herein.

As indicated above, FIG. 1 is provided as an example. Other examples may differ from what is described with regard to FIG. 1.

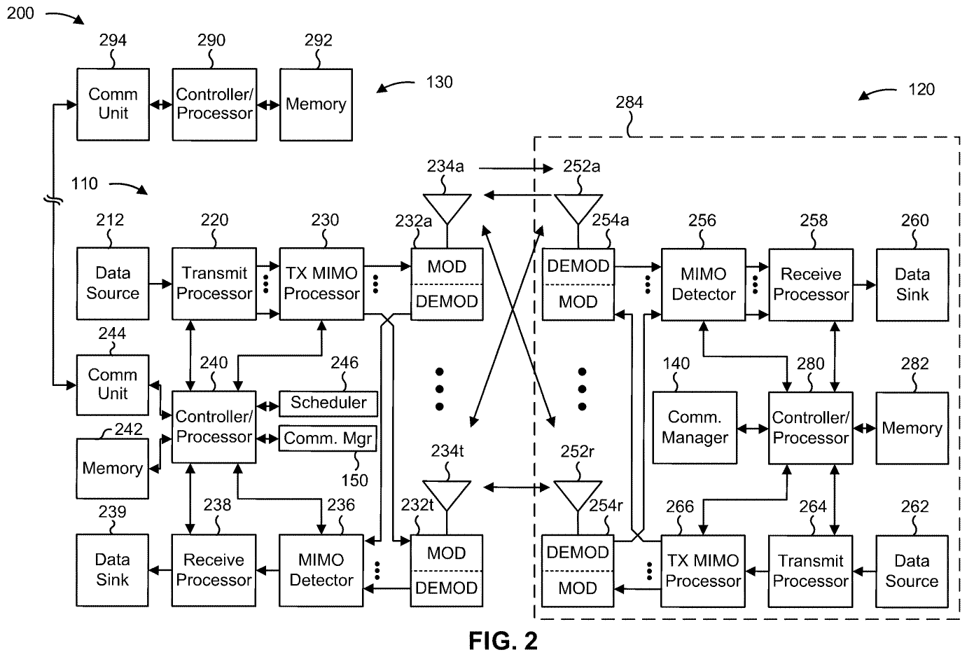

FIG. 2 is a diagram illustrating an example 200 of a network node 110 in communication with a UE 120 in a wireless network 100, in accordance with the present disclosure. The network node 110 may be equipped with a set of antennas 234a through 234t, such as T antennas (T≥1). The UE 120 may be equipped with a set of antennas 252a through 252r, such as R antennas (R≥1). The network node 110 of example 200 includes one or more radio frequency components, such as antennas 234 and a modem 232. In some examples, a network node 110 may include an interface, a communication component, or another component that facilitates communication with the UE 120 or another network node. Some network nodes 110 may not include radio frequency components that facilitate direct communication with the UE 120, such as one or more CUs, or one or more DUs.

At the network node 110, a transmit processor 220 may receive data, from a data source 212, intended for the UE 120 (or a set of UEs 120). The transmit processor 220 may select one or more modulation and coding schemes (MCSs) for the UE 120 based at least in part on one or more channel quality indicators (CQIs) received from that UE 120. The network node 110 may process (e.g., encode and modulate) the data for the UE 120 based at least in part on the MCS(s) selected for the UE 120 and may provide data symbols for the UE 120. The transmit processor 220 may process system information (e.g., for semi-static resource partitioning information (SRPI)) and control information (e.g., CQI requests, grants, and/or upper layer signaling) and provide overhead symbols and control symbols. The transmit processor 220 may generate reference symbols for reference signals (e.g., a cell-specific reference signal (CRS) or a demodulation reference signal (DMRS)) and synchronization signals (e.g., a primary synchronization signal (PSS) or a secondary synchronization signal (SSS)). A transmit (TX) multiple-input multiple-output (MIMO) processor 230 may perform spatial processing (e.g., precoding) on the data symbols, the control symbols, the overhead symbols, and/or the reference symbols, if applicable, and may provide a set of output symbol streams (e.g., T output symbol streams) to a corresponding set of modems 232 (e.g., T modems), shown as modems 232a through 232t. For example, each output symbol stream may be provided to a modulator component (shown as MOD) of a modem 232. Each modem 232 may use a respective modulator component to process a respective output symbol stream (e.g., for OFDM) to obtain an output sample stream. Each modem 232 may further use a respective modulator component to process (e.g., convert to analog, amplify, filter, and/or upconvert) the output sample stream to obtain a downlink signal. The modems 232a through 232t may transmit a set of downlink signals (e.g., T downlink signals) via a corresponding set of antennas 234 (e.g., T antennas), shown as antennas 234a through 234t.

At the UE 120, a set of antennas 252 (shown as antennas 252a through 252r) may receive the downlink signals from the network node 110 and/or other network nodes 110 and may provide a set of received signals (e.g., R received signals) to a set of modems 254 (e.g., R modems), shown as modems 254a through 254r. For example, each received signal may be provided to a demodulator component (shown as DEMOD) of a modem 254. Each modem 254 may use a respective demodulator component to condition (e.g., filter, amplify, downconvert, and/or digitize) a received signal to obtain input samples. Each modem 254 may use a demodulator component to further process the input samples (e.g., for OFDM) to obtain received symbols. A MIMO detector 256 may obtain received symbols from the modems 254, may perform MIMO detection on the received symbols if applicable, and may provide detected symbols. A receive processor 258 may process (e.g., demodulate and decode) the detected symbols, may provide decoded data for the UE 120 to a data sink 260, and may provide decoded control information and system information to a controller/processor 280. The term “controller/processor” may refer to one or more controllers, one or more processors, or a combination thereof. A channel processor may determine a reference signal received power (RSRP) parameter, a received signal strength indicator (RSSI) parameter, a reference signal received quality (RSRQ) parameter, and/or a CQI parameter, among other examples. In some examples, one or more components of the UE 120 may be included in a housing 284.

The network controller 130 may include a communication unit 294, a controller/processor 290, and a memory 292. The network controller 130 may include, for example, one or more devices in a core network. The network controller 130 may communicate with the network node 110 via the communication unit 294.

One or more antennas (e.g., antennas 234a through 234t and/or antennas 252a through 252r) may include, or may be included within, one or more antenna panels, one or more antenna groups, one or more sets of antenna elements, and/or one or more antenna arrays, among other examples. An antenna panel, an antenna group, a set of antenna elements, and/or an antenna array may include one or more antenna elements (within a single housing or multiple housings), a set of coplanar antenna elements, a set of non-coplanar antenna elements, and/or one or more antenna elements coupled to one or more transmission and/or reception components, such as one or more components of FIG. 2.

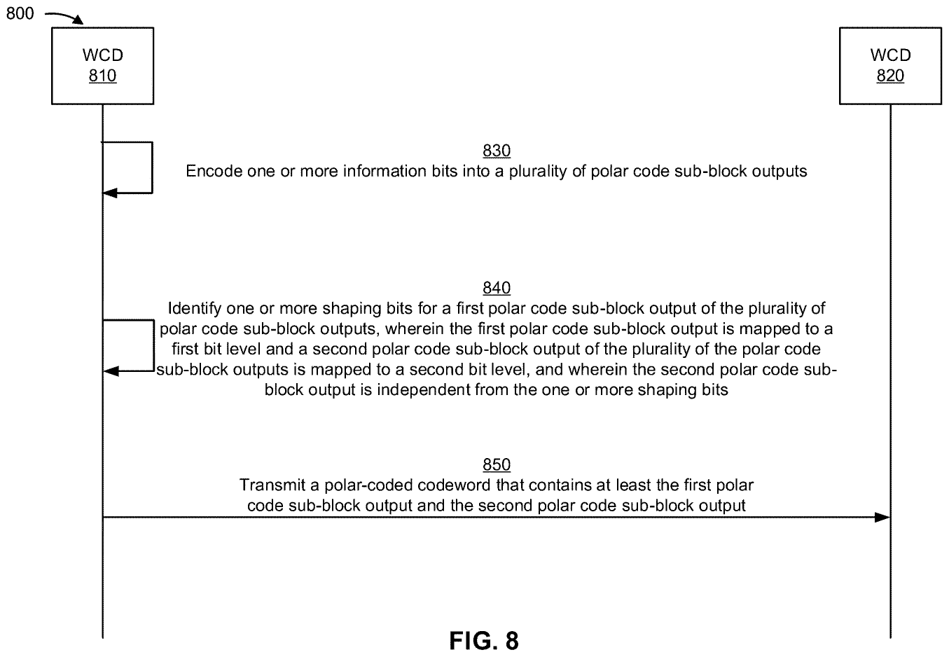

On the uplink, at the UE 120, a transmit processor 264 may receive and process data from a data source 262 and control information (e.g., for reports that include RSRP, RSSI, RSRQ, and/or CQI) from the controller/processor 280. The transmit processor 264 may generate reference symbols for one or more reference signals. The symbols from the transmit processor 264 may be precoded by a TX MIMO processor 266 if applicable, further processed by the modems 254 (e.g., for DFT-s-OFDM or CP-OFDM), and transmitted to the network node 110. In some examples, the modem 254 of the UE 120 may include a modulator and a demodulator. In some examples, the UE 120 includes a transceiver. The transceiver may include any combination of the antenna(s) 252, the modem(s) 254, the MIMO detector 256, the receive processor 258, the transmit processor 264, and/or the TX MIMO processor 266. The transceiver may be used by a processor (e.g., the controller/processor 280) and the memory 282 to perform aspects of any of the methods described herein (e.g., with reference to FIGS. 8-22).

At the network node 110, the uplink signals from UE 120 and/or other UEs may be received by the antennas 234, processed by the modem 232 (e.g., a demodulator component, shown as DEMOD, of the modem 232), detected by a MIMO detector 236 if applicable, and further processed by a receive processor 238 to obtain decoded data and control information sent by the UE 120. The receive processor 238 may provide the decoded data to a data sink 239 and provide the decoded control information to the controller/processor 240. The network node 110 may include a communication unit 244 and may communicate with the network controller 130 via the communication unit 244. The network node 110 may include a scheduler 246 to schedule one or more UEs 120 for downlink and/or uplink communications. In some examples, the modem 232 of the network node 110 may include a modulator and a demodulator. In some examples, the network node 110 includes a transceiver. The transceiver may include any combination of the antenna(s) 234, the modem(s) 232, the MIMO detector 236, the receive processor 238, the transmit processor 220, and/or the TX MIMO processor 230. The transceiver may be used by a processor (e.g., the controller/processor 240) and the memory 242 to perform aspects of any of the methods described herein (e.g., with reference to FIGS. 8-22).

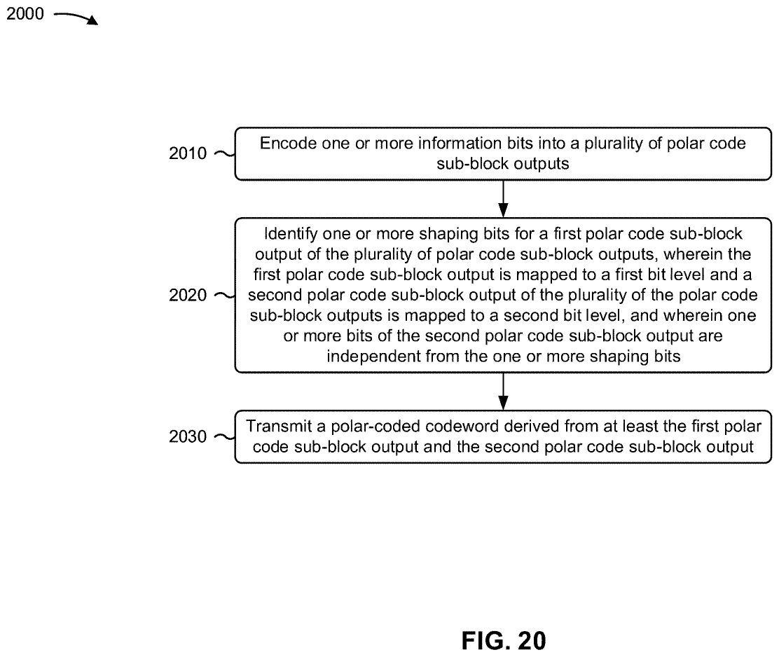

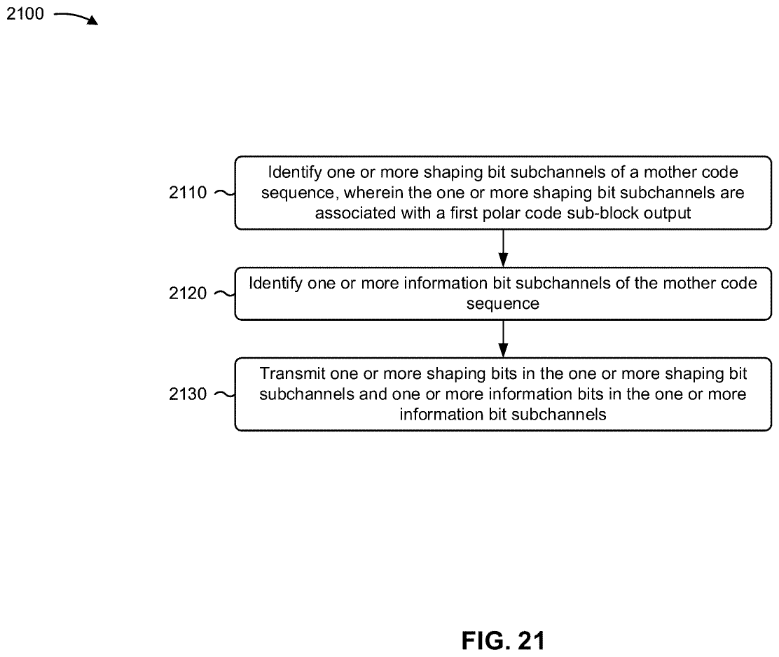

The controller/processor 240 of the network node 110, the controller/processor 280 of the UE 120, and/or any other component(s) of FIG. 2 may perform one or more techniques associated with shaping bits for polar coding, as described in more detail elsewhere herein. For example, the controller/processor 240 of the network node 110, the controller/processor 280 of the UE 120, and/or any other component(s) of FIG. 2 may perform or direct operations of, for example, process 2000 of FIG. 20, process 2100 of FIG. 21, and/or other processes as described herein. The memory 242 and the memory 282 may store data and program codes for the network node 110 and the UE 120, respectively. In some examples, the memory 242 and/or the memory 282 may include a non-transitory computer-readable medium storing one or more instructions (e.g., code and/or program code) for wireless communication. For example, the one or more instructions, when executed (e.g., directly, or after compiling, converting, and/or interpreting) by one or more processors of the network node 110 and/or the UE 120, may cause the one or more processors, the UE 120, and/or the network node 110 to perform or direct operations of, for example, process 2000 of FIG. 20, process 2100 of FIG. 21, and/or other processes as described herein. In some examples, executing instructions may include running the instructions, converting the instructions, compiling the instructions, and/or interpreting the instructions, among other examples. In some aspects, the wireless communication device described herein is the network node 110, is included in the network node 110, includes one or more components of the network node 110 shown in FIG. 2, is the UE 120, is included in the UE 120, or includes one or more components of the UE 120 shown in FIG. 2.

In some aspects, the wireless communication device includes means for encoding one or more information bits into a plurality of polar code sub-block outputs; means for identifying one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits; and/or means for transmitting a polar-coded codeword derived from at least the first polar code sub-block output and the second polar code sub-block output. In some aspects, the means for the wireless communication device to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246. In some aspects, the means for the wireless communication device to perform operations described herein may include, for example, one or more of communication manager 140, antenna 252, modem 254, MIMO detector 256, receive processor 258, transmit processor 264, TX MIMO processor 266, controller/processor 280, or memory 282.

In some aspects, the wireless communication device includes means for identifying one or more shaping bit subchannels of a mother code sequence, wherein the one or more shaping bit subchannels are associated with a first polar code sub-block output; means for identifying one or more information bit subchannels of the mother code sequence; and/or means for transmitting one or more shaping bits in the one or more shaping bit subchannels and one or more information bits in the one or more information bit subchannels. In some aspects, the means for the wireless communication device to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246. In some aspects, the means for the wireless communication device to perform operations described herein may include, for example, one or more of communication manager 140, antenna 252, modem 254, MIMO detector 256, receive processor 258, transmit processor 264, TX MIMO processor 266, controller/processor 280, or memory 282.

While blocks in FIG. 2 are illustrated as distinct components, the functions described above with respect to the blocks may be implemented in a single hardware, software, or combination component or in various combinations of components. For example, the functions described with respect to the transmit processor 264, the receive processor 258, and/or the TX MIMO processor 266 may be performed by or under the control of the controller/processor 280.

As indicated above, FIG. 2 is provided as an example. Other examples may differ from what is described with regard to FIG. 2.

Deployment of communication systems, such as 5G NR systems, may be arranged in multiple manners with various components or constituent parts. In a 5G NR system, or network, a network node, a network entity, a mobility element of a network, a RAN node, a core network node, a network element, a base station, or a network equipment may be implemented in an aggregated or disaggregated architecture. For example, a base station (such as a Node B (NB), an evolved NB (eNB), an NR base station, a 5G NB, an access point (AP), a TRP, or a cell, among other examples), or one or more units (or one or more components) performing base station functionality, may be implemented as an aggregated base station (also known as a standalone base station or a monolithic base station) or a disaggregated base station. “Network entity” or “network node” may refer to a disaggregated base station, or to one or more units of a disaggregated base station (such as one or more CUs, one or more DUs, one or more RUs, or a combination thereof).

An aggregated base station (e.g., an aggregated network node) may be configured to utilize a radio protocol stack that is physically or logically integrated within a single RAN node (e.g., within a single device or unit). A disaggregated base station (e.g., a disaggregated network node) may be configured to utilize a protocol stack that is physically or logically distributed among two or more units (such as one or more CUs, one or more DUs, or one or more RUs). In some examples, a CU may be implemented within a network node, and one or more DUs may be co-located with the CU, or alternatively, may be geographically or virtually distributed throughout one or multiple other network nodes. The DUs may be implemented to communicate with one or more RUs. Each of the CU, DU, and RU also can be implemented as virtual units, such as a virtual central unit (VCU), a virtual distributed unit (VDU), or a virtual radio unit (VRU), among other examples.

Base station-type operation or network design may consider aggregation characteristics of base station functionality. For example, disaggregated base stations may be utilized in an IAB network, an open radio access network (O-RAN (such as the network configuration sponsored by the O-RAN Alliance)), or a virtualized radio access network (vRAN, also known as a cloud radio access network (C-RAN)) to facilitate scaling of communication systems by separating base station functionality into one or more units that can be individually deployed. A disaggregated base station may include functionality implemented across two or more units at various physical locations, as well as functionality implemented for at least one unit virtually, which can enable flexibility in network design. The various units of the disaggregated base station can be configured for wired or wireless communication with at least one other unit of the disaggregated base station.

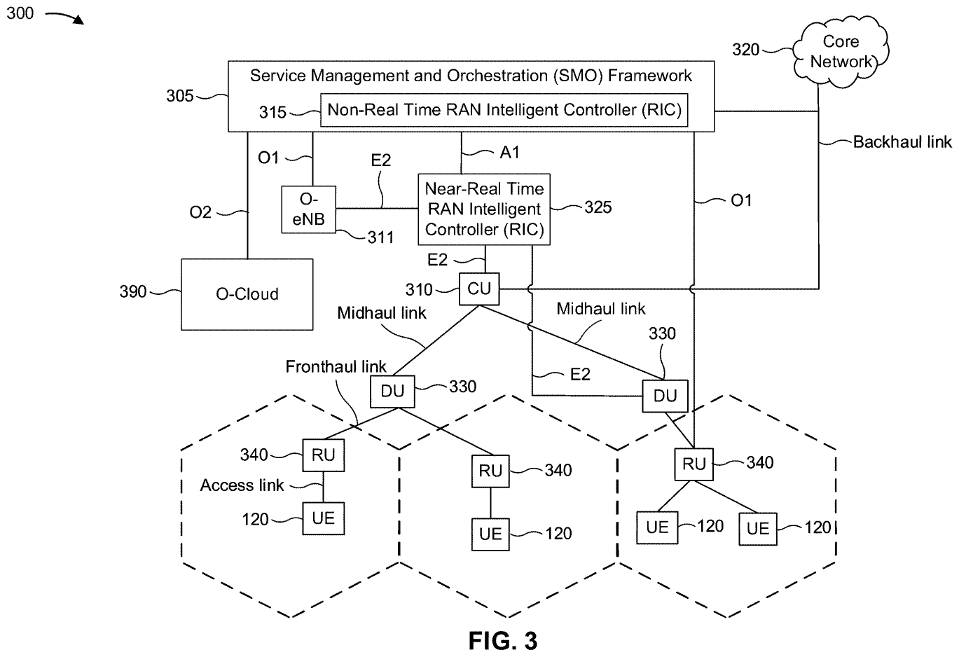

FIG. 3 is a diagram illustrating an example disaggregated base station architecture 300, in accordance with the present disclosure. The disaggregated base station architecture 300 may include a CU 310 that can communicate directly with a core network 320 via a backhaul link, or indirectly with the core network 320 through one or more disaggregated control units (such as a Near-RT RIC 325 via an E2 link, or a Non-RT RIC 315 associated with a Service Management and Orchestration (SMO) Framework 305, or both). A CU 310 may communicate with one or more DUs 330 via respective midhaul links, such as through F1 interfaces. Each of the DUs 330 may communicate with one or more RUs 340 via respective fronthaul links. Each of the RUs 340 may communicate with one or more UEs 120 via respective radio frequency (RF) access links. In some implementations, a UE 120 may be simultaneously served by multiple RUs 340.

Each of the units, including the CUs 310, the DUs 330, the RUs 340, as well as the Near-RT RICs 325, the Non-RT RICs 315, and the SMO Framework 305, may include one or more interfaces or be coupled with one or more interfaces configured to receive or transmit signals, data, or information (collectively, signals) via a wired or wireless transmission medium. Each of the units, or an associated processor or controller providing instructions to one or multiple communication interfaces of the respective unit, can be configured to communicate with one or more of the other units via the transmission medium. In some examples, each of the units can include a wired interface, configured to receive or transmit signals over a wired transmission medium to one or more of the other units, and a wireless interface, which may include a receiver, a transmitter or transceiver (such as an RF transceiver), configured to receive or transmit signals, or both, over a wireless transmission medium to one or more of the other units.

In some aspects, the CU 310 may host one or more higher layer control functions. Such control functions can include radio resource control (RRC) functions, packet data convergence protocol (PDCP) functions, or service data adaptation protocol (SDAP) functions, among other examples. Each control function can be implemented with an interface configured to communicate signals with other control functions hosted by the CU 310. The CU 310 may be configured to handle user plane functionality (for example, Central Unit-User Plane (CU-UP) functionality), control plane functionality (for example, Central Unit-Control Plane (CU-CP) functionality), or a combination thereof. In some implementations, the CU 310 can be logically split into one or more CU-UP units and one or more CU-CP units. A CU-UP unit can communicate bidirectionally with a CU-CP unit via an interface, such as the E1 interface when implemented in an O-RAN configuration. The CU 310 can be implemented to communicate with a DU 330, as necessary, for network control and signaling.

Each DU 330 may correspond to a logical unit that includes one or more base station functions to control the operation of one or more RUs 340. In some aspects, the DU 330 may host one or more of a radio link control (RLC) layer, a medium access control (MAC) layer, and one or more high physical (PHY) layers depending, at least in part, on a functional split, such as a functional split defined by the 3GPP. In some aspects, the one or more high PHY layers may be implemented by one or more modules for FEC encoding and decoding, scrambling, and modulation and demodulation, among other examples. In some aspects, the DU 330 may further host one or more low PHY layers, such as implemented by one or more modules for a fast Fourier transform (FFT), an inverse FFT (iFFT), digital beamforming, or physical random access channel (PRACH) extraction and filtering, among other examples. Each layer (which also may be referred to as a module) can be implemented with an interface configured to communicate signals with other layers (and modules) hosted by the DU 330, or with the control functions hosted by the CU 310.

Each RU 340 may implement lower-layer functionality. In some deployments, an RU 340, controlled by a DU 330, may correspond to a logical node that hosts RF processing functions or low-PHY layer functions, such as performing an FFT, performing an iFFT, digital beamforming, or PRACH extraction and filtering, among other examples, based on a functional split (for example, a functional split defined by the 3GPP), such as a lower layer functional split. In such an architecture, each RU 340 can be operated to handle over the air (OTA) communication with one or more UEs 120. In some implementations, real-time and non-real-time aspects of control and user plane communication with the RU(s) 340 can be controlled by the corresponding DU 330. In some scenarios, this configuration can enable each DU 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements, which may be managed via an operations and maintenance interface (such as an O1 interface). For virtualized network elements, the SMO Framework 305 may be configured to interact with a cloud computing platform (such as an open cloud (O-Cloud) platform 390) to perform network element life cycle management (such as to instantiate virtualized network elements) via a cloud computing platform interface (such as an 02 interface). Such virtualized network elements can include, but are not limited to, CUs 310, DUs 330, RUs 340, non-RT RICs 315, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with each of one or more RUs 340 via a respective O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (such as via an A1 interface) the Near-RT RIC 325. The Near-RT RIC 325 may be configured to include a logical function that enables near-real-time control and optimization of RAN elements and resources via data collection and actions over an interface (such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (such as reconfiguration via an O1 interface) or via creation of RAN management policies (such as A1 interface policies).

As indicated above, FIG. 3 is provided as an example. Other examples may differ from what is described with regard to FIG. 3.

Joint coding and shaping (e.g., probabilistic amplitude shaping (PAS)) may perform FEC coding and shaping in a single code. For example, joint coding and shaping may use a single polar code with both frozen bits and shaping bits. For example, joint coding and shaping may enable placement of both shaping bits and information bits within a transmission. Shaping bits may be used to shape the transmitted symbols to a lower transmit power and, thus, improve a capacity for efficiency.

Joint coding and shaping may be suitable for small block length packets, such as control information (e.g., physical downlink control channel (PDCCH)). With joint coding and shaping, the information bits may be decoded once, after FEC decoding, which may enable lower complexity than separate coding and PAS. Joint coding and shaping may not preclude multiple codewords for different bit-levels.

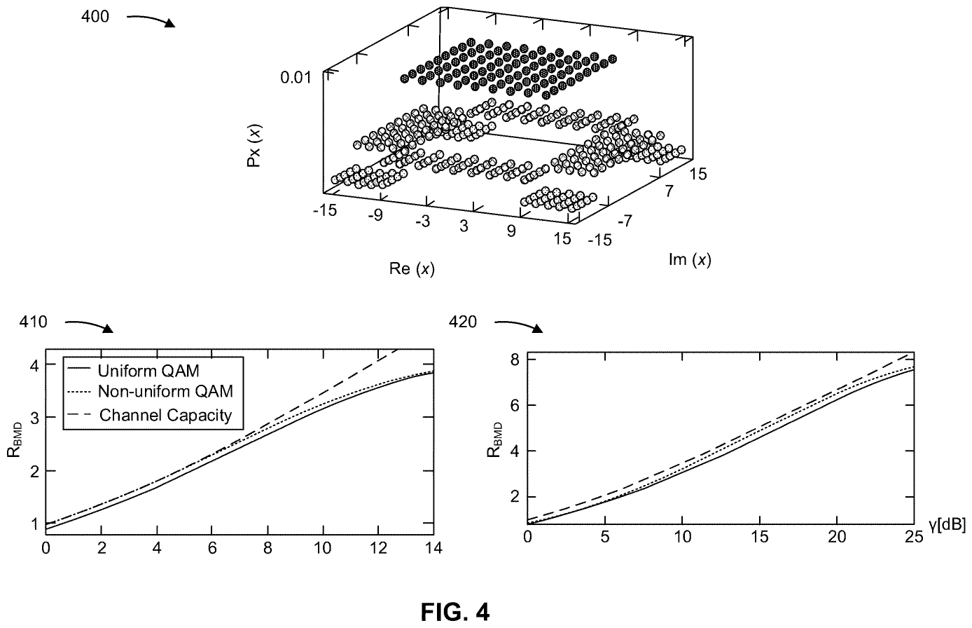

FIG. 4 is a diagram illustrating examples 400, 410, and 420 associated with polar codes having integrated probabilistic shaping, in accordance with the present disclosure.

Example 400 illustrates a probability distribution of quadrature amplitude modulation (QAM) symbols where the quantity of bit levels is 8 (e.g., for 256-QAM), the probability of bits being 1 in subvectors of a generated vector is 0.25, and the rest of the bits have equal probability of being 1 or 0. In example 400, only the most significant bit level may be shaped according to a target probability. Examples 410 and 420 are plots that illustrate an achievable rate RBMD for Gray-labeled 16-QAM and 256-QAM, respectively, according to a uniform distribution and according to a non-uniform distribution provided in example 400.

As indicated above, FIG. 4 is provided as an example. Other examples may differ from what is described with respect to FIG. 4.

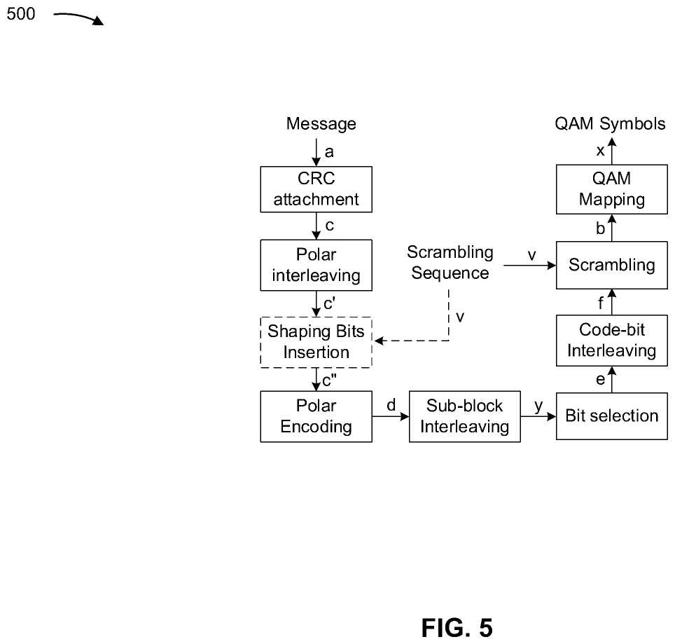

FIG. 5 is a diagram illustrating an example 500 associated with coding and modulation operations for control channels for joint coding and shaping, in accordance with the present disclosure.

As shown by the block labeled “CRC attachment,” a transmitter appends cyclic redundancy check (CRC) bits to a payload vector a to produce vector c. The transmitter polar-interleaves the vector c to generate vector c′, and inserts shaping bits to generate vector c″. The transmitter may further perform polar encoding to generate a vector (or codeword) d, re-order the vector d using a sub-block interleaver to a vector y, and perform bit selection to generate a rate-matched vector e. The transmitter may interleave vector e to generate vector f, perform scrambling of vector f to generate vector b, and map vector b to channel input symbols x.

As indicated above, FIG. 5 is provided as an example. Other examples may differ from what is described with respect to FIG. 5.

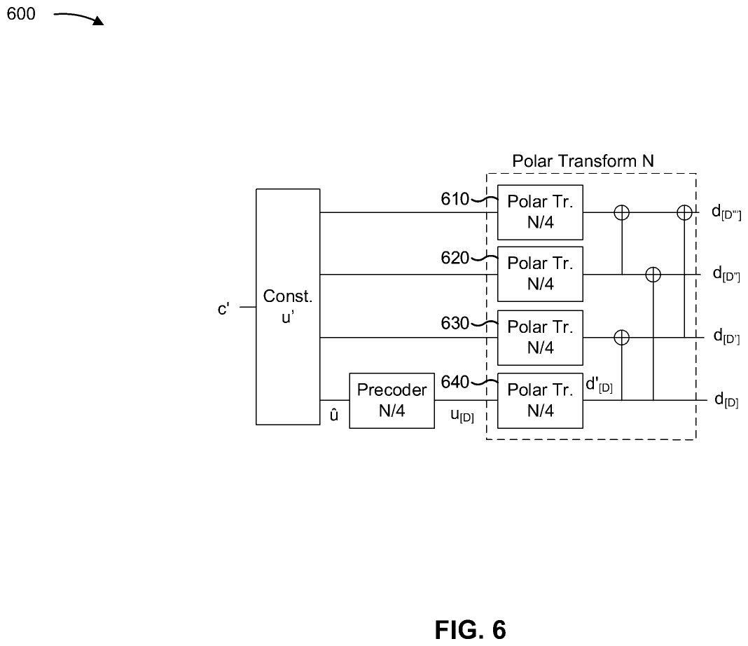

FIG. 6 is a diagram illustrating an example 600 associated with polar precoding and transformation for joint coding and shaping, in accordance with the present disclosure.

As shown, a vector u′ of length N may be constructed from the vector c′. The most reliable S indices of u′ may be left empty, with the most reliable remaining indices filled with the vector c′ and the rest of the indices filled with zeros as frozen bits.

Subvector û, having length N/(M/2), may be extracted from the vector u′ and fed to a precoder that generates shaping bits using a polar decoder of length N/4 to construct the vector u_{[} [symbol] _{]}. The vector u_{[} [symbol] _{]}, and other vectors extracted from subvector û (each having length N/4), may be fed to respective polar transforms (e.g., polar kernels) 610, 620, 630, and 640 that operate on length N/4 vectors. Each polar transform 610-640 may output a vector. For example, polar transform 640 outputs vector d′[ [symbol] ]. Based on various XOR operations (as represented by XOR gates ⊕), example 600 may output vectors d[ [symbol] ], d[ [symbol] ′], d[ [symbol] ″], and d[ [symbol] ″], where [symbol] , [symbol] ′, [symbol] ″, and [symbol] ″ are indices or blocks of a polar-coded codeword.

In example 600, the shaping bits are placed at the most reliable bit position of the most reliable sub-block. The target distribution p generates a target log-likelihood ratio (LLR) of

$$log \frac{1 - p}{p}$$

at d′[ [symbol] ], which may be set to

$$Λ = log ( \frac{1 - p}{p} ) ( - 2 \cdot \overline{v} [ 𝒟 ] + 1 ) ,$$

which accounts for interleaving and scrambling. Block

$$𝒟 ∈ [ \frac{3}{4} N \sim N - 1 ]$$

maps to the location of the most significant bits (without full triangle interleaving).

As indicated above, FIG. 6 is provided as an example. Other examples may differ from what is described with respect to FIG. 6.

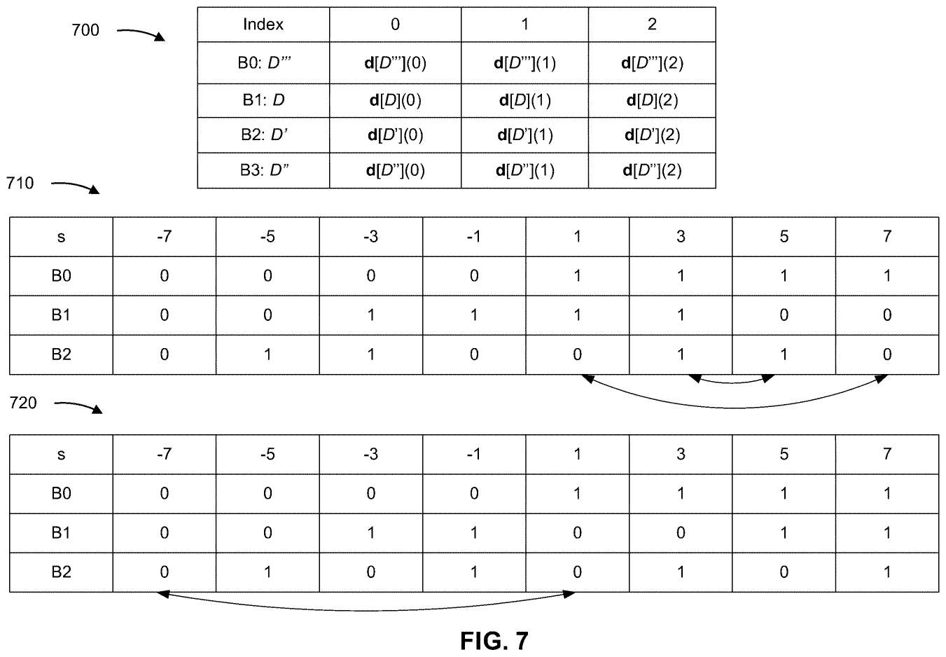

With continuing reference to FIG. 6, FIG. 7 is a diagram illustrating examples 700, 710, and 720 that demonstrate how example 610 may involve excessive transmit power, in accordance with the present disclosure. Example 610 may involve excessive transmit power because d[ [symbol] ′] ~ d[ [symbol] ′″] are modified by d[ [symbol] ]=d′[ [symbol] ] via additional polarization stages. As shown in example 610, d[ [symbol] ′] ~ d[ [symbol] ″] are results of XOR operations that use d′[ [symbol] ] as an input (or that use an input that itself is the result of an XOR operation that uses d′[ [symbol] ] as an input).

Example 700 is a table that maps bit levels to indexes (e.g., bit positions) of d[ [symbol] ] ~d[ [symbol] ) “′]. B0 is the sign bit level, B1 is the most significant bit level, and B2 and B3 are less significant bit levels than B1. B0 is mapped to d[ [symbol] ”′], B1 is mapped to d[ [symbol] ], and B2 and B3 are mapped to d[ [symbol] ′] and d[ [symbol] ″], respectively. Because of the XOR relationships shown in example 610, d[ [symbol] ] may impact all other bit levels (e.g., B0, B2, and B3).

LLR is a transmit power metric that may be modeled as LLRᵢ=|gray([0, d[ [symbol] ′](i), d[ [symbol] ″](i)])|²−|gray([1, d[ [symbol] ′](i), d[ [symbol] ″](i)])|². This relationship implies that d[ [symbol] ′]~d[ [symbol] ″] depending on d′[ [symbol] ] can cause the transmit power increase. The relationship is based on Gray mapping, which is a technique that orders binary numbers such that successive values differ by one bit. For example, in a Gray order mapping, the decimal number 5 corresponds to 111 in binary and the decimal number 6 corresponds to 101 in binary. By contrast, in a natural order mapping, the decimal number 5 corresponds to 101 in binary and the decimal number 6 corresponds to 110 in binary. Natural order mapping (e.g., natural order labeling) would change the relationship described above such that B0 is mapped to the most significant bits, which impacts the symbol power most significantly. Thus, regardless of whether Gray mapping or natural order mapping is employed, d′[ [symbol] ] modifying d[ [symbol] ′]~d[ [symbol] ′″] can increase transmit power.

Example 710 shows a table that maps the bit levels B0, B1, and B2 to symbols via Gray mapping. B0 contains sign bits, B1 contains the most significant bits, and B2 contains less significant bits than B1. The symbols are shown in the top row (e.g., −7, −5, etc.). In example 710, more power is reduced by changing symbol 7 to symbol 1 via shaping bits than by changing symbol 5 to symbol 3.

Symbol 7 corresponds to bits [1,0,0] and symbol 1 corresponds to bits [1,1,0]. Thus, changing symbol 7 to symbol 1 involves changing the B1 bit from 0 to 1. Because symbol 5 corresponds to bits [1,0,1] and symbol 3 corresponds to bits [1,1,1], changing symbol 5 to symbol 3 also involves changing the B1 bit from 0 to 1. Because the lower significant bit in the B2 bit level can be modified by the shaping of the most significant bit at the B1 level, the B2 bit may be undetermined when the B1 bit changes from 0 to 1. Thus, under the framework of example 610, changing the B1 bit from 0 to 1 may not enable prioritizing changing symbol 7 to symbol 1 over changing symbol 5 to symbol 3. As a result, example 610 involves excessive transmit power.

Example 720 shows a table that maps the bit levels B0, B1, and B2 to symbols via natural order mapping. Similar issues exist in example 720 with respect to loss of transmit power savings. For example, changing the B0 bit for symbol-7 from 0 to 1 may change symbol-7 to symbol 1, but, because of the framework of example 610, changing the B0 bit may also have undetermined consequences on other bit levels (e.g., B1 and/or B2). Unlike in example 710, where B1 has the largest impact on symbol (transmit) power and values of the sign bits contained in bit level B0 do not change symbol power, in example 720, B0 (the sign bits) have the largest impact on symbol power.

As indicated above, FIG. 7 is provided as an example. Other examples may differ from what is described with respect to FIG. 7.

FIG. 8 is a diagram illustrating an example 800 associated with identifying shaping bits for a polar-coded codeword, in accordance with the present disclosure. As shown in FIG. 8, a wireless communication device 810 and a wireless communication device 810 may communicate with one another. The wireless communication device 810 and the wireless communication device 820 may be any suitable devices. For example, one or more of the wireless communication device 810 or the wireless communication device 820 may be a network node (e.g., network node 110), a UE (e.g., UE 120), or the like.

As shown by reference number 830, the wireless communication device 810 may encode one or more information bits into a plurality of polar code sub-block outputs. For example, the wireless communication device 810 may input a plurality of information bits (e.g., a message) into a plurality of polar transforms corresponding to the polar code sub-block outputs.

As shown by reference number 840, the wireless communication device 810 may identify one or more shaping bits for a first polar code sub-block output of the plurality of polar code sub-block outputs. The first polar code sub-block output is mapped to a first bit level and a second polar code sub-block output of the plurality of the polar code sub-block outputs is mapped to a second bit level. For example, the first bit level may be a most significant bit level associated with the polar-coded codeword and the second bit level may be mapped to a less significant bit level than the most significant bit level.

The second polar code sub-block output may be independent from the one or more shaping bits. For example, the second polar code sub-block output may not be impacted or modified by the shaping bits. For example, there may be no XOR gate that takes as input the second polar code sub-block output and the one or more shaping bits.

The second polar code sub-block output being independent from the one or more shaping bits may enable the wireless communication device 810 to use reduced transmit power (e.g., less transmit power than a wireless communication device that employs the framework of example 610). The second polar code sub-block output being independent from the one or more shaping bits may enable the second polar code sub-block output to be predetermined or fixed such that the shaping bits do not change the value of the second polar code sub-block output. For example, d[ [symbol] ](i) and d[ [symbol] ](i) may be fixed.

For instance, unlike the framework of example 610, the second polar code sub-block output being independent from the one or more shaping bits may enable the wireless communication device 810 to prioritize changing symbol 7 to symbol 1 over changing symbol 5 to symbol 3 as discussed above in connection with example 710 (FIG. 7). The wireless communication device 810 may prioritize changing symbol 7 to symbol 1 over changing symbol 5 to symbol 3 because changing a bit in B1 does not change a bit in B2. As a result, the bits in B2 may be predetermined or fixed, which may enable the wireless communication device 810 to determine the value of a symbol before changing a bit in B1. Thus, the second polar code sub-block output being independent from the one or more shaping bits may enable reducing or minimizing transmit power.

As shown by reference number 850, the wireless communication device 810 may transmit a polar-coded codeword derived from at least the first polar code sub-block output and the second polar code sub-block output. For example, the wireless communication device 810 may transmit a polar-coded codeword using reduced transmit power based on the second polar code sub-block output being independent from the one or more shaping bits.

In some examples, the polar-coded codeword is based at least in part on a Gray mapping, and the first polar code sub-block output does not map to any sign bits. For example, the first polar code sub-block output may map to bit level B1 as shown in FIG. 7, where bit level B0 contains the sign bits. Basing the polar-coded codeword at least in part on the Gray mapping and not mapping the first polar code sub-block output to any sign bits may make example 800 compatible with Gray mapping techniques.

In some examples, the polar-coded codeword is based at least in part on a natural order mapping, and the first polar code sub-block output may be mapped to one or more sign bits. For example, the first polar code sub-block output may map to bit level B0 as shown in example 720, where bit level B0 contains the sign bits. Basing the polar-coded codeword at least in part on the natural order mapping and mapping the first polar code sub-block output to one or more sign bits may make example 800 compatible with natural order mapping techniques.

As indicated above, FIG. 8 is provided as an example. Other examples may differ from what is described with respect to FIG. 8.

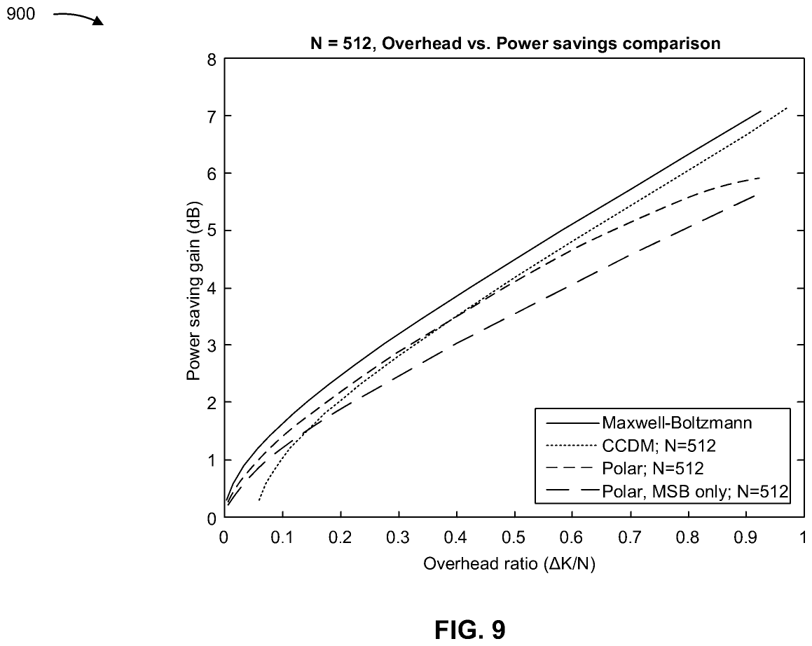

FIG. 9 is a diagram illustrating an example 900 associated with power reduction associated with identifying shaping bits for a polar-coded codeword, in accordance with the present disclosure. Example 900 includes a plot of overhead versus power savings for various techniques with a block length (N) of 512. The power savings may be a targeting power reduction that is equivalent to a targeting probability. The plot shows, for reference, power savings associated with a theoretical upper limit (“Maxwell-Boltzmann”) and power savings associated with a constant composition distribution matcher (CCDM) (“CCDM; N=512”).

The plot shows power savings using the techniques of example 610 (“Polar, MSB only; N=512)”). The power savings achieved using the techniques of example 610 may involve an LLR value that is constructed with unknown (e.g., unfixed or non-predetermined) less significant bit values. The less significant bit values may be unknown because the less significant bit values depend on shaping bits.

The plot also shows power savings using the techniques of example 800 (“Polar; N=512)”), which may be enabled by the second polar code sub-block output being independent from the one or more shaping bits, as described above in connection with reference number 840 (FIG. 8). The power savings achieved using the techniques of example 800 may involve an LLR value that is constructed with known (e.g., fixed or predetermined) less significant bit values. The less significant bit values may be known because the less significant bit values are independent of shaping bits. The known less significant bit values may provide soft LLR values that improve power savings. For example, example 800 may provide soft LLRs for demodulation such that the quantity of low-transmit-power symbols can be increased.

The power savings associated with example 800 are greater than the power savings associated with example 610. For example, when the shaping rate is near 0.5, the power savings is approximately 0.4 dB. The shaping gain (power savings) may increase with larger constellation sizes (because larger constellation sizes may enable a greater quantity of soft LLR values). Furthermore, the trend of the shaping gain may be similar for different decoder algorithms (e.g., list size, block length, or the like).

As indicated above, FIG. 9 is provided as an example. Other examples may differ from what is described with respect to FIG. 9.

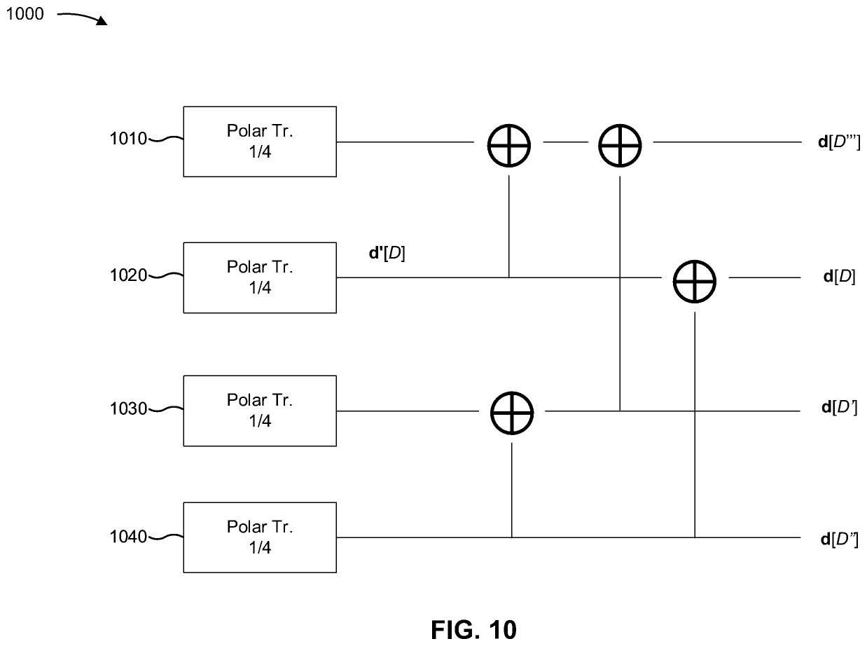

FIG. 10 is a diagram illustrating an example 1000 associated with bits of a polar code sub-block output that are independent from shaping bits, in accordance with the present disclosure.

In example 1000, a transmitter may encode one or more information bits into a plurality of polar code sub-block outputs. For example, the transmitter may encode one or more information bits into one or more outputs of polarization transforms (e.g., polarization kernels) 1010-1040. The transmitter may identify one or more shaping bits for a first polar code sub-block output (e.g., d′[ [symbol] ]). The shaping bit(s) may be placed at the most reliable bit position(s) of d′[ [symbol] ]. In example 1000, the transmitter may use Gray mapping.

The first polar code sub-block output (e.g., d′[ [symbol] ]) may be mapped to a first bit level (e.g., a most significant bits level). A second polar code sub-block output (e.g., the output of polarization transform 1030) may be mapped to a second bit level (e.g., a level that contains less significant bits than the most significant bits). A third polar code sub-block output (e.g., the output of polarization transform 1040) may be mapped to a third bit level (e.g., least significant bits). A fourth polar code sub-block output (e.g., the output of polarization transform 1010) may be mapped to a fourth bit level (e.g., sign bits).

As shown, the second and third polar code sub-block outputs are independent from the one or more shaping bits. For example, d′[ [symbol] ] does not XOR with the output of the polarization transform 1030 or the output of the polarization transform 1040 and, thus, does not impact the less significant bits for purposes of determining the power metric. d′[ [symbol] ] may impact d[ [symbol] ″], which may help to improve the reliability of the shaping bits.

Because d[ [symbol] ″] contains the sign bits, which do not affect the power metric for techniques involving Gray mapping, d′[ [symbol] ] impacting d[ [symbol] ′″] may not interfere with minimizing the transmit power metric. For natural order mapping techniques, the sign bits may affect the power metric and, thus, the transmitter may predetermine bit levels B1 and B2 and then shape the sign bits.

As indicated above, FIG. 10 is provided as an example. Other examples may differ from what is described with respect to FIG. 10.

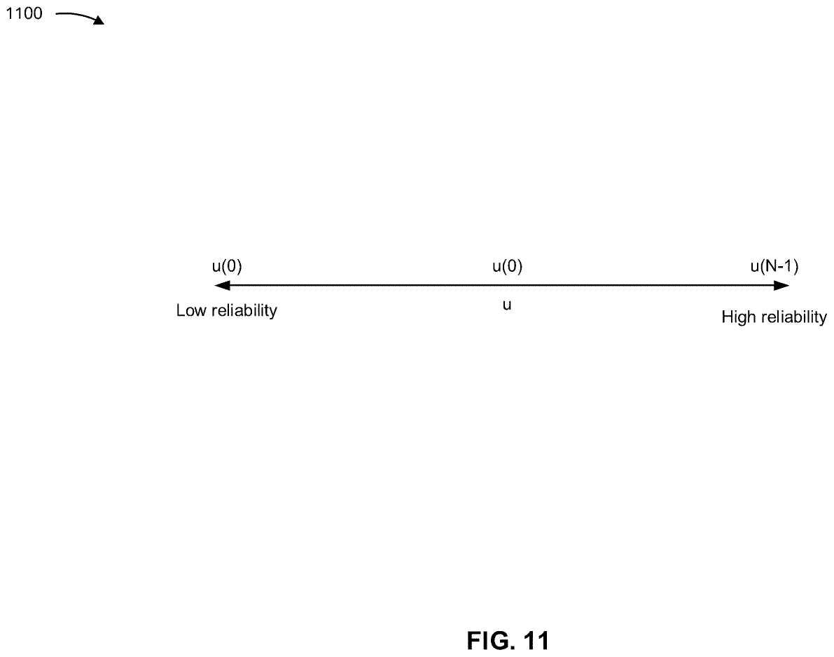

FIG. 11 is a diagram illustrating an example 1100 associated with index reliabilities, in accordance with the present disclosure.

The transmitter may compute an LLR value in accordance with the predetermined bit values that contain the less significant bits. The computation of the LLR value may be modeled as a cover code process. For example, for a linear block code with length (N,K) and GF(2), d=u×G=u₁×G₁+u₂×G₂ where u₁=u( [symbol] ), u₂=u( [symbol] ), G₁=G( [symbol] ), G₂=G( [symbol] ), [symbol] ∪ [symbol] =[0,1, . . . , N−1] and [symbol] ∩ [symbol] =Ø; u₂×G₂=d+u₁×G₁, and where G=F^{⊗n}, n=log₂ N,

$$F = [ \begin{matrix}1 & 0 \\ 1 & 1\end{matrix} ] .$$

Because G is a lower triangular matrix, u(i) may impact d(0~i) and may not impact d(i+1~N−1). If the transmitter obtains the targeting d and u₁×G₁, then the transmitter may compute u₂ by solving a linear code decoder. The reliability order of u may be computed via density evolution or other, simpler methods, such as techniques that are based on polarization weight (PW) sequences. As illustrated by example 1100, a greater index of u may be associated with a higher reliability of u than the reliability associated with a lower index.

As indicated above, FIG. 11 is provided as an example. Other examples may differ from what is described with respect to FIG. 11.

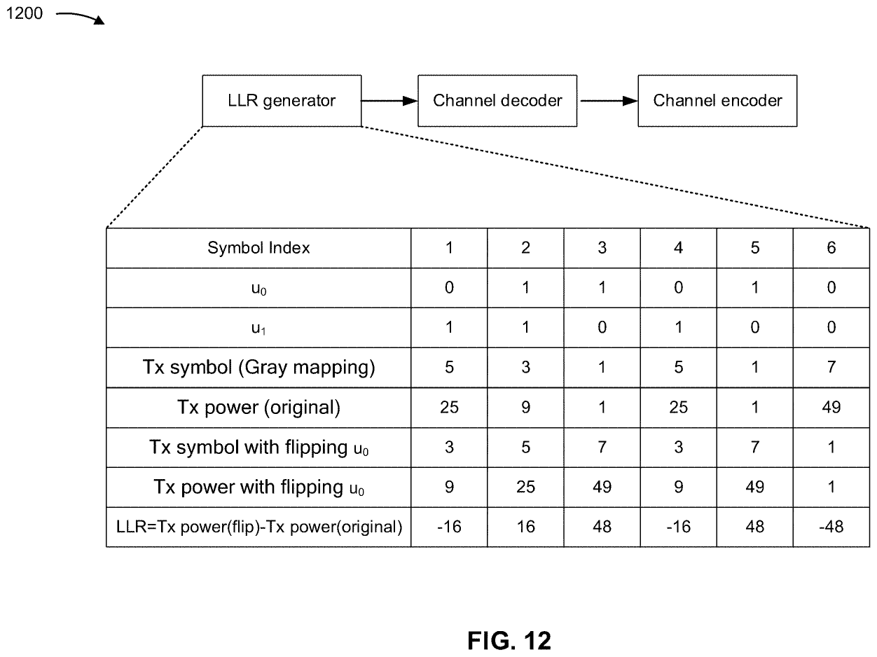

FIG. 12 is a diagram illustrating an example 1200 associated with a channel code shaper that utilizes block code for shaping via an LLR generator, in accordance with the present disclosure.

In example 1200, the transmitter may input information (e.g., uniform or unshaped bits) into the channel code shaper. The LLR generator may generate LLRs for each symbol index based on the power that would be saved by flipping the bit in that symbol index. For example, for original transmission bits with (u₀, u₁)=(1,1), flipping the u₀ bit results in (u₀, u₁)=(0,1), which is associated with a power change of 16 dB. The LLR generator may enable the transmitter to generate a target cover code that maximizes power savings after performing bit-masking operations.

The transmitter may determine the LLR value and perform polar decoding as follows. As a preliminary matter, the transmitter may determine frozen bits, shaping bits, and information bit polar code subchannel index as [symbol] , S, and I, respectively, where [symbol] ∪S∪I=[0,1, . . . , N−1] and [symbol] ∩S∩I=Ø. The shaping bits and information bits sequence may be represented as s, k. The transmitter may compute d[ [symbol] ]~d[ [symbol] ′″] via polar-transform with d=u×G, where u(S)=s and u(I)=k, and where S represents the subchannel index, s is the vector of the shaping bits, and/represents the information bits. In this example, [symbol] may be the index set with N/4~N/2−1; [symbol] ′ may be the index set with N/2~3/4 N−1, [symbol] ″ may be the index set with 3/4 N~N−1, and [symbol] ′″ may be the index set with 0~N/4−1. With this preliminary framework, the transmitter may determine the shaping bit sequence s that reduces or minimizes the total transmit power

$$P = {\sum }_{i = 0}^{N / M - 1} {Q}_{i}^{2} ,$$

where Qᵢ is the i^{th} QAM (e.g., amplitude-shift keying (ASK)) symbol and

$${Q}_{i}^{2} = {\vert gray ( d [ 𝒟 ] ( i ) , d [ {𝒟}^{′} ] ( i ) , d [ {𝒟}^{″} ] ( i ) ) \vert}^{2} .$$

In a first operation, the transmitter may determine d[ [symbol] ], d[ [symbol] ′], and d[ [symbol] ″] without shaping bits. For example, the transmitter may insert only the information bits in u(I)=k, where u(S)=0. Thus, the transmitter may place the information bits on the polar code transformation subchannels and predetermine the outputs for the lower significant bit values (e.g., corresponding to d[ [symbol] ′] and d[ [symbol] ″]). The transmitter may also determine d[ [symbol] ] by performing a polar code transform d=u×G, where d[ [symbol] ′] and d[ [symbol] ″] modify (e.g., based on the presence of one nor more XOR gates) d[D].

In a second operation, the transmitter may identify the one or more shaping bits based at least in part on an LLR value. For example, the transmitter may generate the LLR value for the i^{th} index of d′[ [symbol] ] based on the relation LLRᵢ=|gray([0⊕d[ [symbol] ](i), d[ [symbol] ′](i), d[ [symbol] ″](i)])|²−|gray(1⊕d[ [symbol] ](i), d[ [symbol] ′](i), d[ [symbol] ″](i))|² or the relation LLRᵢ=(|gray([0, d[ [symbol] ′](i), d[ [symbol] ″](i)])|²−|gray([1, d[ [symbol] ′](i), d[ [symbol] ′](i)])|²)×(1−2×d[ [symbol] ′](i)). Identifying the one or more shaping bits based at least in part on an LLR value may enable the transmitter to use the LLR value to reduce or minimize the transmit power. For example, a target LLR may be used to determine the shaping bits, which enables energy reduction via shaping gain.

In a third operation, in some examples, the transmitter may identify the one or more shaping bits by performing a polar-decoding operation associated with the first polar code sub-block output. For example, the transmitter may perform polar-decoding on only one-fourth of the total polar code. The transmitter may treat the shaping bits as information bits for decoding and may treat all leftover positions (including information bits positioned in the first polar code sub-block output) as frozen bits. Identifying the one or more shaping bits by performing the polar-decoding operation associated with the first polar code sub-block output may enable the transmitter to identify the shaping bit(s) for 2ⁿ block lengths.

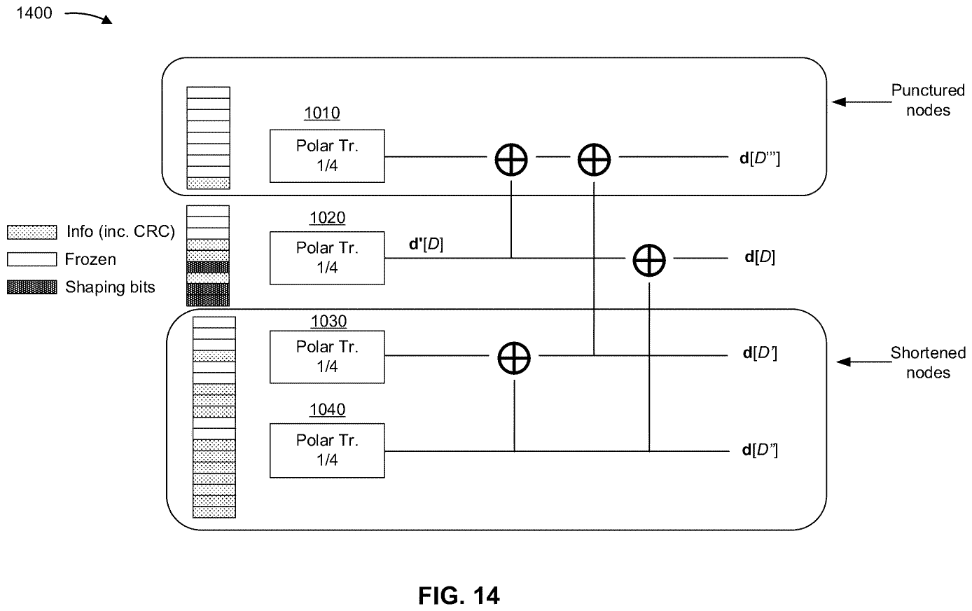

In the third operation, in some examples, the transmitter may identify the one or more shaping bits by polar-decoding the polar-coded codeword based at least in part on an association of each polar code sub-block output of the plurality of polar code sub-block outputs, other than the first polar code sub-block output (e.g., d′[ [symbol] ]), with a punctured node or with a shortened node. For example, the transmitter may decode over the full-sized, length-N polar code by setting the upper sub-block outputs (e.g., the sub-block output d[ [symbol] ′″]) as punctured nodes and lower sub-block outputs (e.g., the sub-block outputs d[ [symbol] ′] and d[ [symbol] ″]) as shortened nodes. Techniques involving punctured and shortened nodes are described further below in connection with FIG. 14. Identifying the one or more shaping bits by polar-decoding the polar-coded codeword based at least in part on the association of each polar code sub-block output of the plurality of polar code sub-block outputs, other than the first polar code sub-block output, as a punctured node or as a shortened node may enable the transmitter to identify the shaping bit(s) for non-2ⁿ block lengths.

Providing the transmitter with the decoding capabilities described above in connection with the third operation may enable the transmitter to calculate the shaping bits. The third operation may also involve the transmitter performing successive cancellation or list-decoding, after which the shaping bits sequence s may be obtained.

In a fourth operation, the transmitter may re-calculate the shaped most significant bit values by re-running the polar transform (e.g., the transmitter may re-calculate d=u×G). The transmitter may also assign the shaping bits to shaping bit subchannels such that u(S)=s and u(I)=k.

As indicated above, FIG. 12 is provided as an example. Other examples may differ from what is described with respect to FIG. 12.

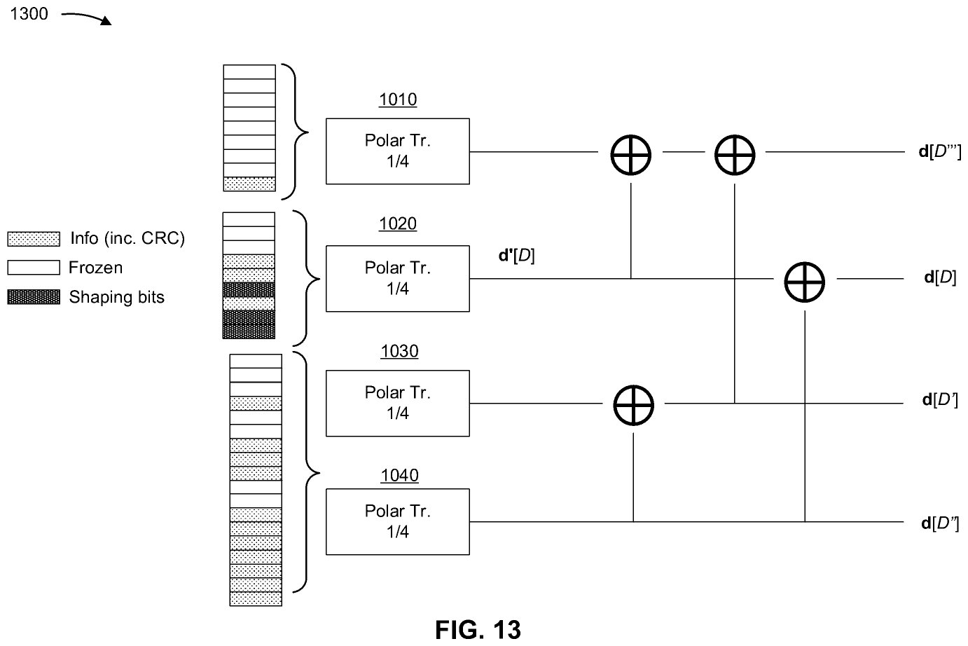

FIG. 13 is a diagram illustrating an example 1300 associated with a structure in which information bits, frozen bits, and shaping bits are assigned to subchannels that are associated with a plurality of polar code sub-block outputs, in accordance with the present disclosure. Example 1300 may include a structure that is similar to example 1000.

As shown, the transmitter may assign, to the fourth polar code sub-block output (e.g., the output of polar transform 1010) frozen bit subchannels and an information bit subchannel. The transmitter may assign, to d′[ [symbol] ], frozen bit subchannels, information bit subchannels, and shaping bit subchannels. The transmitter may assign, to the polar code sub-block outputs of polar transforms 1030 and 1040, frozen bit subchannels and information bit subchannels. The structure of example 1300 is arranged such that the shaping bits do not impact the information bits associated with d[ [symbol] ′] or d[ [symbol] ″].

As indicated above, FIG. 13 is provided as an example. Other examples may differ from what is described with respect to FIG. 13.

FIG. 14 is a diagram illustrating an example 1400 associated with calculating shaping bits based on an association of each polar code sub-block output of the plurality of polar code sub-block outputs, other than d′[ [symbol] ], with a punctured node or with a shortened node, in accordance with the present disclosure.

Example 1400 illustrates a polarization graph in which the polar code sub-block output of polar transform 1010 is associated with a punctured node, and the polar code sub-block outputs of polar transforms 1030 and 1040 are associated with shortened nodes. The transmitter may calculate the shaping bits by performing a reversed decoding operation where the punctured node is treated as having zero LLR and the shortened nodes are treated as having infinite LLRs. As a result, the decoded shaping bits may be jointly transmitted with information bits (with or without CRC bits) by a single polar code.

As indicated above, FIG. 14 is provided as an example. Other examples may differ from what is described with respect to FIG. 14.

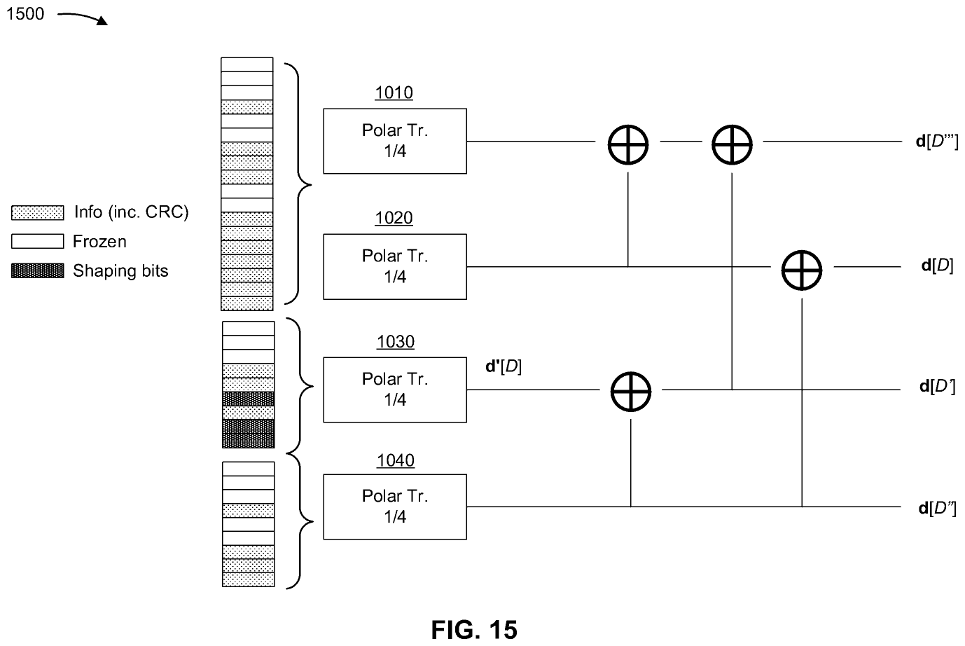

FIG. 15 is a diagram illustrating an example 1500 associated with a polar code sub-block output that is associated with a quantity of polarization iterations, in accordance with the present disclosure. Example 1500 may include a structure that is similar to examples 1000 and 1300. However, whereas in example 1300 the shaping bits were inserted in the polarization transform 1020, in example 1500 the shaping bits are inserted in the polarization transform 1030.

As shown, the transmitter may assign, to the polar code sub-block outputs of polar transforms 1010, 1020, and 1040, frozen bit subchannels and information bit subchannels. The transmitter may assign, to the polar code sub-block output d′[ [symbol] ], frozen bit subchannels, information bit subchannels, and shaping bit subchannels. The structure of example 1500 is arranged such that the shaping bits do not impact the information bits associated with d[ [symbol] ′] or d[ [symbol] ″].

d′[ [symbol] ] may be associated with a quantity of polarization iterations. For example, the polarization transform 1020 may be associated with fewer polarization iterations than the polarization transform 1030. As a result, the subchannel reliability associated with the polarization transform 1020 may be lower than the subchannel reliability associated with the polarization transform 1030, which may degrade the shaping bit protection and thus impact performance on the polarization transform 1020.

For example, while placing the shaping bits at the polarization transform 1020 can increase shaping performance, the FEC performance at the polarization transform 1020 may be degraded compared to the polarization transform 1030. The successive cancellation decoding process involved in polar coding may cause the polarization transform 1020 to be less reliable and the polarization transform 1030 to be more reliable.

Thus, the quantity of polarization iterations associated with the polarization transform 1030, where the shaping bits are placed, may be based at least in part on a target subchannel reliability associated with the one or more shaping bits or based at least in part on a target FEC performance associated with the one or more shaping bits. In a first example, the transmitter may place shaping bits in the polarization transform 1040, which may generate the largest FEC protection for the shaping bits while incurring the largest losses to shaping gain. In a second example, the transmitter may place shaping bits in the polarization transform 1010, which may generate the lowest FEC protection for the shaping bits while enabling a maximum shaping gain. The second example may apply to natural order labeling, where sign bits may be shaped to obtain a shaping gain. In a third example, which corresponds to example 1500, the shaping bits may be placed at the polarization transform 1030. The subchannel reliability for the polarization transform 1020 and the subchannel reliability for the polarization transform 1030 may differ.

Basing the quantity of polarization iterations with the target subchannel reliability and the target FEC performance may enable the transmitter to balance the shaping gain and FEC gain to arrive at a target shaping performance. As a result, the transmitter may manage the tradeoff between shaping gain and FEC gain. For high coding rates, the gain(s) may be leveraged. The transmitter may properly tune the quantity of shaping bits, coding rate, shaping bits subchannel locations, or the like to achieve the appropriate balance between the shaping gain and the FEC gain.

As indicated above, FIG. 15 is provided as an example. Other examples may differ from what is described with respect to FIG. 15.

In some cases, placement of the shaping bits and information bits within subchannels may not satisfy a target FEC performance threshold and/or a target shaping performance threshold. Diminished FEC performance can increase errors associated with the transmission of the shaping bits and/or the information bits. Diminished shaping performance can increase the transmit power of the transmission.

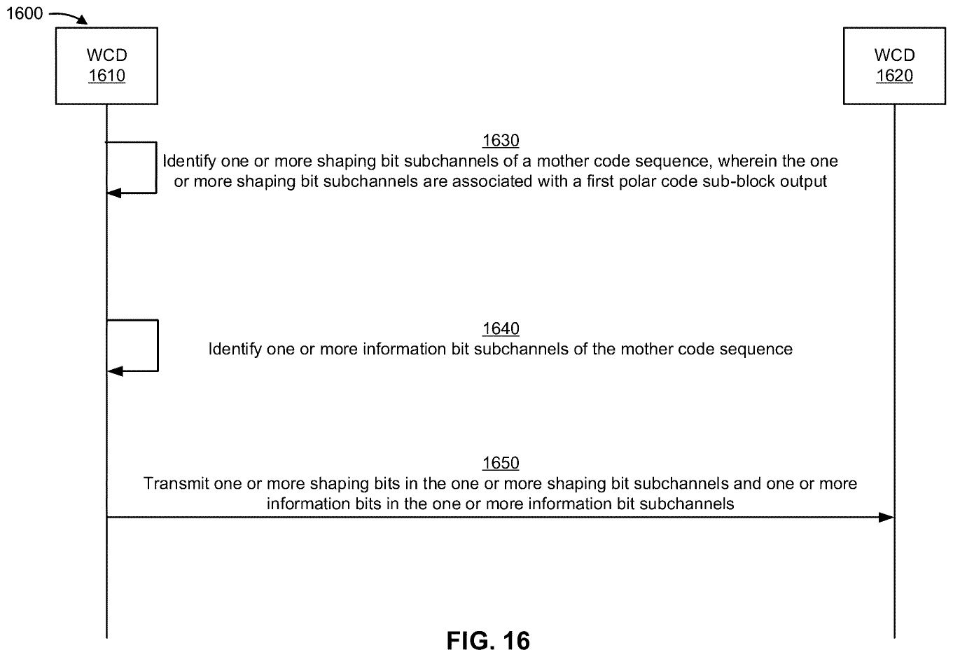

FIG. 16 is a diagram illustrating an example 1600 associated with sequence construction for joint coding and shaping with polar codes, in accordance with the present disclosure. As shown in FIG. 16, a wireless communication device 1610 and a wireless communication device 1610 may communicate with one another. The wireless communication device 1610 and the wireless communication device 1620 may be any suitable devices. For example, one or more of the wireless communication device 1610 or the wireless communication device 1620 may be a network node (e.g., network node 110), a UE (e.g., UE 120), or the like.

As shown by reference number 1630, the wireless communication device 1610 may identify one or more shaping bit subchannels of a mother code sequence. In some examples, the mother code sequence may be input into one or more polar transforms. The one or more shaping bit subchannels are associated with a first polar code sub-block output. As shown by reference number 1640, the wireless communication device 1610 may identify one or more information bit subchannels of the mother code sequence.

For example, the shaping bit subchannels and/or the information bit subchannels may be identified by ordering subchannels based on reliability. The order (or “sequence”) of the subchannels may be determined using density evolution, beta expansion, providing a metric that determines the ordering of the reliable and unreliable channels, or the like. In some examples, a polar code sequence may enable use of up to 512 reliable subchannels.

Identifying the shaping bit subchannels (e.g., the locations of the shaping bits) and/or the information bit subchannels (e.g., subchannels suitable for the information bits) may enable the wireless communication device 1610 to control the FEC performance and/or shaping performance of the corresponding transmission. For example, the wireless communication device 1610 may assign shaping bits to shaping bit subchannels and information bits to information bit subchannels based on a target FEC performance threshold and/or a target shaping performance threshold. Thus, the wireless communication device 1610 may achieve a target balance between FEC performance and shaping performance.

As shown by reference number 1650, the wireless communication device 1610 may transmit one or more shaping bits in the one or more shaping bit subchannels and one or more information bits in the one or more information bit subchannels. For example, the transmission that includes the one or more shaping bits in the one or more shaping bit subchannels and that includes one or more information bits in the one or more information bit subchannels may achieve the target FEC performance and the target shaping performance.

As indicated above, FIG. 16 is provided as an example. Other examples may differ from what is described with respect to FIG. 16.

In a first aspect, identifying the one or more shaping bit subchannels includes identifying the one or more shaping bit subchannels based at least in part on first reliability metrics of subchannels associated with at least the first polar code sub-block output (e.g., d′[ [symbol] ]) and second reliability metrics of subchannels associated with at least a second polar code sub-block (e.g., an output of polar transforms 1030 or 1040). For example, the wireless communication device 1610 may determine shaping bit subchannels based on an order or sequence of subchannels associated with (e.g., assigned to) any of the polar transforms in a polarization graph, assign information bits to any remaining subchannels associated with any of the polar code sub-block outputs (e.g., the most reliable remaining subchannels), and assign frozen bits to any remaining subchannels that were not assigned a shaping bit or an information bit.

For example, in a first operation for identifying the one or more shaping bit subchannels based at least in part on first reliability metrics of subchannels associated with at least the first polar code sub-block output and second reliability metrics of subchannels associated with at least a second polar code sub-block output, the wireless communication device 1610 may obtain a length-N reliability vector for N polar subchannels W=[W⁰~W^{N-1}], where Nis the codeword length. For example, the wireless communication device 1610 may obtain a length-N reliability vector via density evolution, fractally enhanced kernel (FRANK) techniques, or the like.

In a second operation for identifying the one or more shaping bit subchannels based at least in part on first reliability metrics of subchannels associated with at least the first polar code sub-block output and second reliability metrics of subchannels associated with at least a second polar code sub-block output, the wireless communication device 1610 may identify the most reliable position W^{S} for the shaping bits by identifying the most reliable subchannels in [symbol] where

$${W}^{𝒟} = [ {W}^{𝒟 ( 0 )} , ... , {W}^{𝒟 ( \frac{N}{4} - 1 )} ] ,$$

and where [symbol] is the location set of the most significant bits that are impacted by the shaping bits

$$( e . g . , 𝒟 = [ \frac{N}{4} ∼ \frac{N}{2} - 1 ] ) .$$

For example, [symbol] may be a subvector associated with the polar transform 1020. The shaping bits set S may be selected from the most reliable subchannels (or subchannels associated with the smallest bit error) in [symbol] .

In a third operation for identifying the one or more shaping bit subchannels based at least in part on first reliability metrics of subchannels associated with at least the first polar code sub-block output and second reliability metrics of subchannels associated with at least a second polar code sub-block output, the wireless communication device 1610 may identify the information bits subchannels W^{I} by allocating the most reliable subchannels in W^{S̅} for the information bits, where S̅∪S= [1~N]. For example, W^{I} may be selected from the most reliable subchannels (or subchannels associated with the smallest bit error) in W^{S̅}.

Identifying the one or more shaping bit subchannels based at least in part on first reliability metrics of subchannels associated with at least the first polar code sub-block output and second reliability metrics of subchannels associated with at least a second polar code sub-block output may provide strong FEC protection. For example, the wireless communication device 1610 may identify the shaping bit subchannels based on reliability metrics of subchannels associated with at least the first and second polar code sub-block outputs (e.g., based on reliability metrics of N subchannels), which may provide a large sample size of subchannels and thereby improve FEC performance.

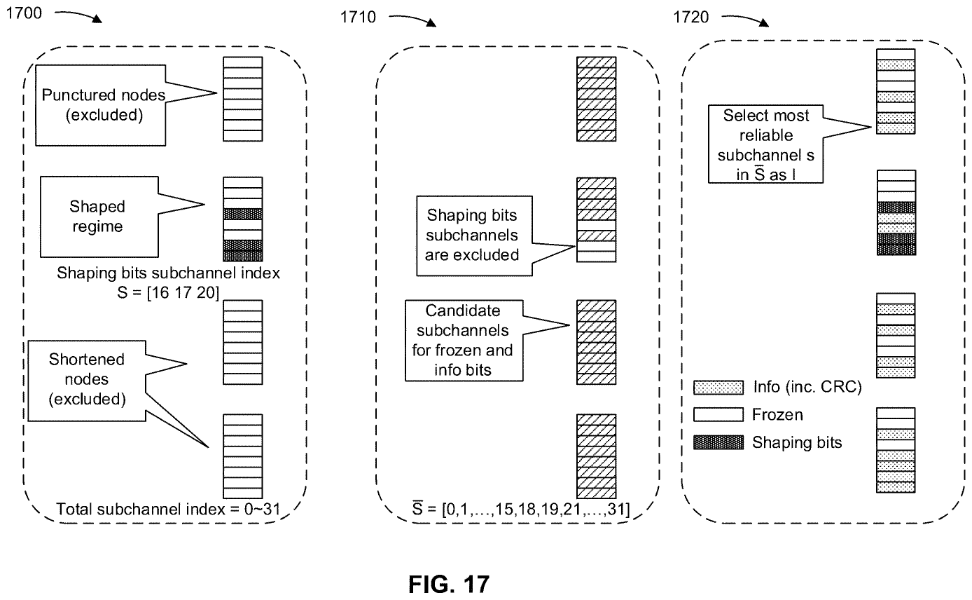

FIG. 17 is a diagram illustrating examples 1700, 1710, and 1720 associated with a second aspect involving identifying the one or more shaping bit subchannels based at least in part on first reliability metrics of subchannels associated with the first polar code sub-block output independent of any second reliability metric of subchannels associated with any second polar code sub-block output, in accordance with the present disclosure. For example, the transmitter may determine the reliability of subchannels within a subchannel region (e.g., among subchannels corresponding to polar transform 1020). For example, the wireless communication device 1610 may determine shaping bit subchannels based on an order or sequence of subchannels associated with (e.g., assigned to) the polar transform that will operate on the shaping bits, assign information bits to any remaining subchannels associated with any of the polar code sub-block outputs (e.g., the most reliable remaining subchannels), and assign frozen bits to any remaining subchannels that were not assigned a shaping bit or an information bit.

As shown by reference number 1700, a transmitter may determine

$${W}_{2}^{𝒟}$$

and S. For example, the transmitter may obtain a length-| [symbol] | reliability for most significant bit locations that are shaped by shaping bits,

$${W}_{2}^{𝒟} ,$$

where |′ [symbol] | is the length of [symbol] . For example, the transmitter may obtain

$${W}_{2}^{𝒟}$$

based on the polarization graph shown in FIG. 14, which includes a designated punctured node and designated shortened nodes. For example, the transmitter may perform, on the polarization graph, density evolution, a Gaussian approximation method (e.g., Gaussian evolution), or the like. The transmitter may identify the most reliable position for the shaping bits by identifying the most reliable subchannels in

$${W}_{2}^{𝒟} .$$

The shaping bits set S may be selected from the most reliable subchannels (or subchannels associated with the smallest bit error) in

$${W}_{2}^{𝒟} .$$

As shown by reference number 1710, the transmitter may determine S̅. For example, the transmitter may obtain a length-N reliability vector for N polar subchannels

$${W}_{1} = [ {W}_{1}^{0} ∼ {W}_{1}^{N - 1} ] .$$

For example, the transmitter may obtain a length-N reliability vector via density evolution, FRANK techniques, or the like. The transmitter may identify the information bits subchannels by allocating the most reliable subchannels in

$${W}_{1}^{\overline{S}}$$

for the information bits, where S̅∪S=[0~N−1] and

$${W}_{1}^{\overline{S}}$$

is selected in

$${W}_{1}^{N} .$$

As shown by reference number 1720, the transmitter may determine I (e.g., the information bit subchannels). For example, W^{I} may be selected from the most reliable subchannels (or subchannels associated with the smallest bit error) in W^{S̅}.

Identifying the one or more shaping bit subchannels based at least in part on first reliability metrics of subchannels associated with the first polar code sub-block output independent of any second reliability metric of subchannels associated with any second polar code sub-block output may improve shaping performance (e.g., based on redetermining the locations of the shaping bits). For example, the second aspect may accurately identify the reliable subchannels within

$${W}_{2}^{𝒟} ,$$

which may enable the shaping bits to provide a high shaping gain (e.g., large energy savings).

As indicated above, FIG. 17 is provided as an example. Other examples may differ from what is described with respect to FIG. 17.

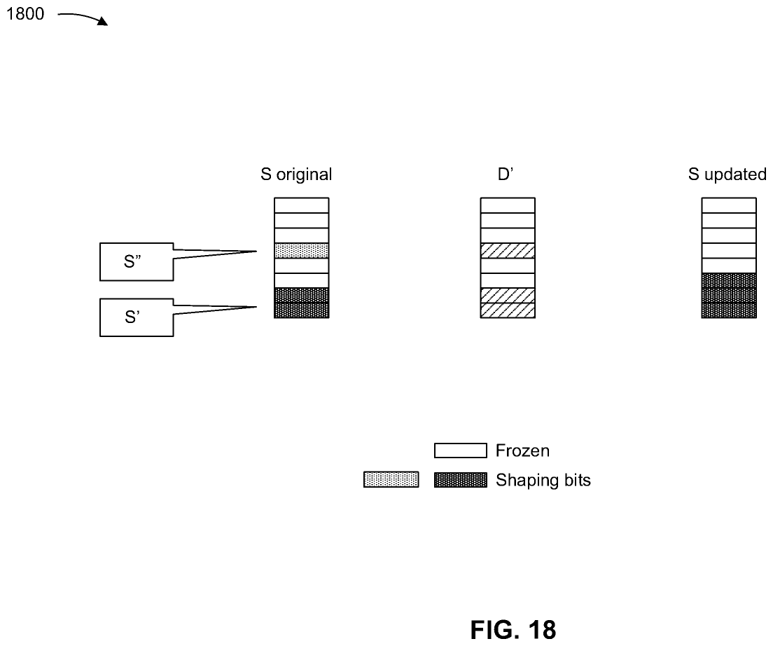

FIG. 18 is a diagram illustrating an example 1800 in which a transmitter may replace one or more candidate shaping bit subchannels (e.g., “S original”) with the one or more shaping bit subchannels (e.g., “S updated”) based at least in part on one or more reliability metrics of the one or more candidate shaping bit subchannels, in accordance with the present disclosure. In some examples, example 1800 may be compatible with at least the second aspect.

For example, the transmitter may exclude one or more unreliable (e.g., candidate) subchannels in

$${W}_{1}^{S}$$

and replace the unreliable subchannel(s) with reliable subchannels

$${W}_{1}^{𝒟} .$$

For example, if S=[S′∪S″], where S″ are the unreliable subchannels in

$${W}_{1}^{S} ,$$

then the subchannels that are to replace S″ may be obtained from [symbol] ′= [symbol] \S. For example, the updated subchannels may be selected from the most reliable subchannels in

$${W}_{1}^{{𝒟}^{′}} .$$

Replacing the candidate shaping bit subchannel(s) with the shaping bit subchannel(s) based at least in part on the reliability metric(s) of the candidate shaping bit subchannel(s) may improve FEC performance of the second aspect.

As indicated above, FIG. 18 is provided as an example. Other examples may differ from what is described with respect to FIG. 18.

Table 1 below compares symbol probabilities associated with the first aspect and with the second aspect. In the example of Table 1, the modulation order 256-QAM is N=512, the shaping rate is 0.27, the shaping bits length Ks=ceil(N/4*0.27)=35 bits,

$$𝒟 = [ \frac{N}{4} \sim \frac{N}{2} - 1 ] ,$$

the rate is 0.8, the quantity of CRC (N_{CRC}) bits is 24, and the information bit length K=ceil(0.8*512)−Ks−N_{CRC}=351 bits.

As shown in Table 1, the second aspect may indicate that the second aspect may be associated with a higher probability of low-index symbols. Thus, the second aspect may be associated with a greater shaping effect. However, as noted, the first aspect may be associated with greater FEC performance than the second aspect.

TABLE 1

| | Symbol-index | | | | | | | |
|---|---|---|---|---|---|---|---|---|
| | 1 | 3 | 5 | 7 | 9 | 11 | 13 | 15 |
| First | 0.180 | 0.172 | 0.160 | 0.138 | 0.112 | 0.091 | 0.078 | 0.070 |
| aspect | | | | | | | | |
| Second | 0.214 | 0.198 | 0.175 | 0.144 | 0.107 | 0.076 | 0.051 | 0.035 |
| aspect | | | | | | | | |

In a third aspect, identifying the one or more shaping bit subchannels may include a combination of identifying the one or more shaping bit subchannels based at least in part on first reliability metrics of subchannels associated with at least the first polar code sub-block output and second reliability metrics of subchannels associated with at least a second polar code sub-block output and identifying the one or more shaping bit subchannels based at least in part on the first reliability metrics independent of the second reliability metrics.

For example, a transmitter may determine shaping bit subchannels based on a first order or sequence of subchannels associated with (e.g., assigned to) any of the polar transforms in a polarization graph and based on a second order or sequence of subchannels associated with (e.g., assigned to) the polar transform that will operate on the shaping bits, assign information bits to any remaining subchannels associated with any of the polar code sub-block outputs (e.g., the most reliable remaining subchannels), and assign frozen bits to any remaining subchannels that were not assigned a shaping bit or an information bit.

In a first operation associated with the third aspect, a transmitter may obtain a length-N reliability vector for N polar subchannels

$${W}_{1}^{[ 1 : N ]} = [ {W}^{1} \sim {W}^{N} ] .$$

For example, the transmitter may obtain a length-N reliability vector via density evolution, FRANK techniques, or the like.

In a second operation associated with the third aspect, the transmitter may obtain a length-| [symbol] | reliability for most significant bit locations that are shaped by shaping bits

$${W}_{2}^{𝒟} .$$

For example, the transmitter may obtain

$${W}_{2}^{𝒟}$$

based on the polarization graph shown in FIG. 14, which includes a designated punctured node and designated shortened nodes. For example, the transmitter may perform, on the polarization graph, density evolution, a Gaussian approximation method (e.g., Gaussian evolution), or the like.

In a third operation associated with the third aspect, the transmitter may obtain a length-| [symbol] | reliability for most significant bit locations that are shaped by shaping bits

$${W}_{3}^{𝒟} = α \times {W}_{1}^{𝒟} + β \times {W}_{2}^{𝒟} .$$

$${W}_{3}^{𝒟}$$

may be a linear combination of

$${W}_{1}^{𝒟}$$

(e.g., a parameter associated with the first aspect) and

$${W}_{2}^{𝒟}$$

(e.g., a parameter associated with the second aspect).

In a fourth operation associated with the third aspect, the transmitter may identify the most reliable position for the shaping bits by identifying the most reliable subchannels in

$${W}_{3}^{𝒟} .$$

The shaping bits set S may be selected from the most reliable subchannels (or subchannels associated with the smallest bit error) in

$${W}_{3}^{𝒟} .$$

In a fifth operation associated with the third aspect, the transmitter may identify the information bits subchannels by allocating the most reliable subchannels in

$${W}_{1}^{\overline{S}}$$

for the information bits, where S̅∪S=[1~N] and

$${W}_{1}^{\overline{S}}$$

is selected from within

$${W}_{1}^{N} .$$

For example, W^{I} may be selected from the most reliable subchannels (or subchannels associated with the smallest bit error) in W^{S̅}.

Identifying the one or more shaping bit subchannels including a combination of identifying the one or more shaping bit subchannels based at least in part on first reliability metrics of subchannels associated with at least the first polar code sub-block output and second reliability metrics of subchannels associated with at least a second polar code sub-block output and identifying the one or more shaping bit subchannels based at least in part on the first reliability metrics independent of the second reliability metrics may enable the transmitter to balance a target FEC performance with a target shaping performance. For example, adjusting the values of α and β may improve the FEC performance or the target shaping performance.

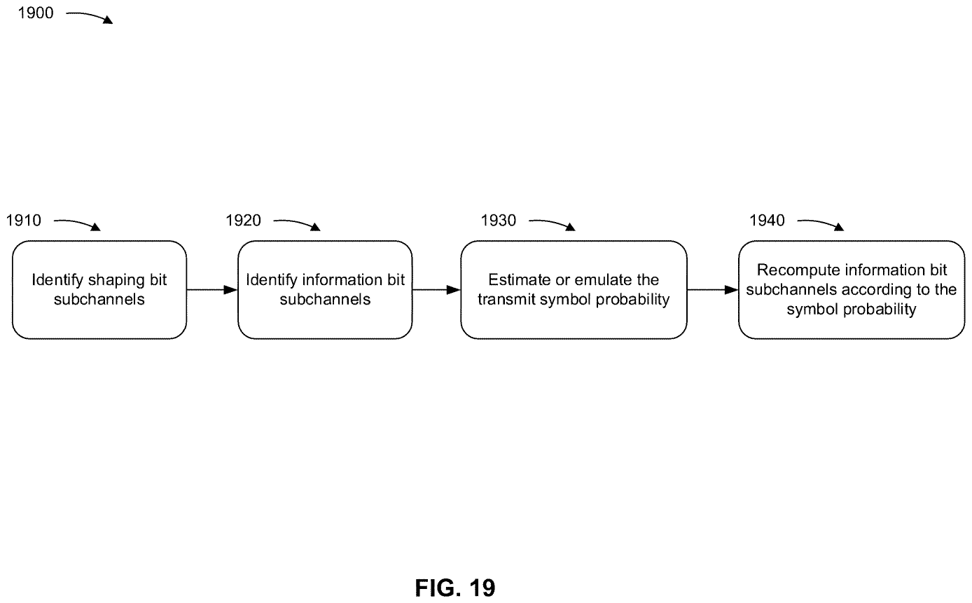

FIG. 19 is a diagram illustrating an example 1900 associated with identifying the one or more information bit subchannels and/or one or more shaping bit subchannels based at least in part on a generated symbol distribution, in accordance with the present disclosure.

As shown by reference number 1910, a transmitter may identify one or more shaping bit subchannels (e.g., the location(s) of the shaping bits). As shown by reference number 1920, the transmitter may identify one or more information bit subchannels (e.g., the location(s) of the information bits). As shown by reference number 1930, the transmitter may estimate or emulate a transmit symbol (e.g., a shaped symbol) probability. For example, the transmitter may update the length-N reliability vector for N polar subchannels W based on the probability associated with one or more shaped symbols.

As shown by reference number 1940, a transmitter may recompute (e.g., identify) the one or more information bit subchannels and/or shaping bit subchannels according to the probability associated with the one or more shaped symbols. For example, the transmitter may recompute the one or more information bit subchannels and/or shaping bit subchannels based on the shaped symbol probability value to compute a capacity of a symmetric channel. The bit level capacity for different bit levels may be associated with the symbol distribution. The transmitter may perform a density evolution (e.g., mutual information density evolution (MI-DE), Gaussian approximation, or the like. The transmitter may use the updated W1 to determine the subchannel index for the one or more information bits. Identifying (e.g., recomputing) the one or more information bit subchannels and/or shaping bit subchannels according to a probability associated with one or more shaped symbols may enhance the subchannel reliability of the shaping.

As indicated above, FIG. 19 is provided as an example. Other examples may differ from what is described with respect to FIG. 19.

FIG. 20 is a diagram illustrating an example process 2000 performed, for example, by a wireless communication device, in accordance with the present disclosure. Example process 2000 is an example where the wireless communication device (e.g., network node 110, UE 120, apparatus 2200, or the like) performs operations associated with shaping bits for polar coding.

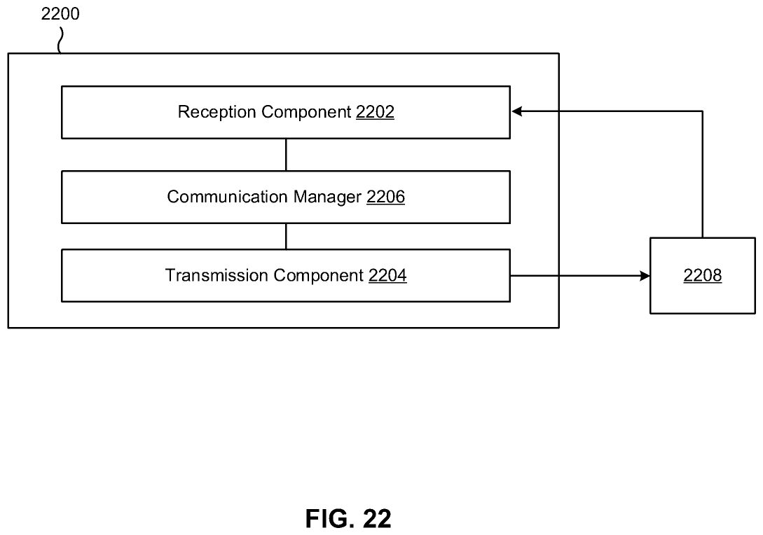

As shown in FIG. 20, in some aspects, process 2000 may include encoding one or more information bits into a plurality of polar code sub-block outputs (block 2010). For example, the wireless communication device (e.g., using communication manager 2206, depicted in FIG. 22) may encode one or more information bits into a plurality of polar code sub-block outputs, as described above.

As further shown in FIG. 20, in some aspects, process 2000 may include identifying one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits (block 2020). For example, the wireless communication device (e.g., using communication manager 2206, depicted in FIG. 22) may identify one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits, as described above.

As further shown in FIG. 20, in some aspects, process 2000 may include transmitting a polar-coded codeword derived from at least the first polar code sub-block output and the second polar code sub-block output (block 2030). For example, the wireless communication device (e.g., using transmission component 2204 and/or communication manager 2206, depicted in FIG. 22) may transmit a polar-coded codeword derived from at least the first polar code sub-block output and the second polar code sub-block output, as described above.

Process 2000 may include additional aspects, such as any single aspect or any combination of aspects described below and/or in connection with one or more other processes described elsewhere herein.

In a first aspect, the first bit level is a most significant bit level associated with the polar-coded codeword.

In a second aspect, alone or in combination with the first aspect, identifying the one or more shaping bits includes identifying the one or more shaping bits based at least in part on an LLR value.

In a third aspect, alone or in combination with one or more of the first and second aspects, identifying the one or more shaping bits includes performing a polar-decoding operation associated with the first polar code sub-block output.

In a fourth aspect, alone or in combination with one or more of the first through third aspects, identifying the one or more shaping bits includes polar-decoding the polar-coded codeword based at least in part on an association of each polar code sub-block output of the plurality of polar code sub-block outputs, other than the first polar code sub-block output, with a punctured node or a shortened node.

In a fifth aspect, alone or in combination with one or more of the first through fourth aspects, the polar-coded codeword is based at least in part on a Gray mapping, and the first polar code sub-block output does not map to any sign bits.

In a sixth aspect, alone or in combination with one or more of the first through fifth aspects, the polar-coded codeword is based at least in part on natural order mapping, and the first polar code sub-block output is mapped to one or more sign bits.

In a seventh aspect, alone or in combination with one or more of the first through sixth aspects, the first polar code sub-block output is associated with a quantity of polarization iterations that is based at least in part on a target subchannel reliability associated with the one or more shaping bits or based at least in part on a target forward error correction performance associated with the one or more shaping bits.

In an eighth aspect, alone or in combination with one or more of the first through seventh aspects, the wireless communication device is a UE.

In a ninth aspect, alone or in combination with one or more of the first through seventh aspects, the wireless communication device is a network node.

Although FIG. 20 shows example blocks of process 2000, in some aspects, process 2000 may include additional blocks, fewer blocks, different blocks, or differently arranged blocks than those depicted in FIG. 20. Additionally, or alternatively, two or more of the blocks of process 2000 may be performed in parallel.

FIG. 21 is a diagram illustrating an example process 2100 performed, for example, by a wireless communication device, in accordance with the present disclosure. Example process 2100 is an example where the wireless communication device (e.g., network node 110, UE 120, apparatus 2200, or the like) performs operations associated with shaping bits for polar coding.

As shown in FIG. 21, in some aspects, process 2100 may include identifying one or more shaping bit subchannels of a mother code sequence, wherein the one or more shaping bit subchannels are associated with a first polar code sub-block output (block 2110). For example, the wireless communication device (e.g., using communication manager 2206, depicted in FIG. 22) may identify one or more shaping bit subchannels of a mother code sequence, wherein the one or more shaping bit subchannels are associated with a first polar code sub-block output, as described above.

As further shown in FIG. 21, in some aspects, process 2100 may include identifying one or more information bit subchannels of the mother code sequence (block 2120). For example, the wireless communication device (e.g., using communication manager 2206, depicted in FIG. 22) may identify one or more information bit subchannels of the mother code sequence, as described above.

As further shown in FIG. 21, in some aspects, process 2100 may include transmitting one or more shaping bits in the one or more shaping bit subchannels and one or more information bits in the one or more information bit subchannels (block 2130). For example, the wireless communication device (e.g., using transmission component 2204 and/or communication manager 2206, depicted in FIG. 22) may transmit one or more shaping bits in the one or more shaping bit subchannels and one or more information bits in the one or more information bit subchannels, as described above.

Process 2100 may include additional aspects, such as any single aspect or any combination of aspects described below and/or in connection with one or more other processes described elsewhere herein.

In a first aspect, identifying the one or more shaping bit subchannels includes identifying the one or more shaping bit subchannels based at least in part on first reliability metrics of subchannels associated with at least the first polar code sub-block output and second reliability metrics of subchannels associated with at least a second polar code sub-block output.

In a second aspect, alone or in combination with the first aspect, identifying the one or more shaping bit subchannels includes identifying the one or more shaping bit subchannels based at least in part on first reliability metrics of subchannels associated with the first polar code sub-block output independent of any second reliability metric of subchannels associated with any second polar code sub-block output.

In a third aspect, alone or in combination with one or more of the first and second aspects, process 2100 includes replacing one or more candidate shaping bit subchannels with the one or more shaping bit subchannels based at least in part on the first reliability metrics.

In a fourth aspect, alone or in combination with one or more of the first through third aspects, identifying the one or more shaping bit subchannels includes a combination of identifying the one or more shaping bit subchannels based at least in part on first reliability metrics of subchannels associated with at least the first polar code sub-block output and second reliability metrics of subchannels associated with at least a second polar code sub-block output, and identifying the one or more shaping bit subchannels based at least in part on the first reliability metrics independent of the second reliability metrics.

In a fifth aspect, alone or in combination with one or more of the first through fourth aspects, identifying the one or more shaping bit subchannels includes recomputing the one or more shaping bit subchannels according to a probability associated with one or more shaped symbols.

In a sixth aspect, alone or in combination with one or more of the first through fifth aspects, the wireless communication device is a UE.

In a seventh aspect, alone or in combination with one or more of the first through fifth aspects, the wireless communication device is a network node.

Although FIG. 21 shows example blocks of process 2100, in some aspects, process 2100 may include additional blocks, fewer blocks, different blocks, or differently arranged blocks than those depicted in FIG. 21. Additionally, or alternatively, two or more of the blocks of process 2100 may be performed in parallel.

FIG. 22 is a diagram of an example apparatus 2200 for wireless communication, in accordance with the present disclosure. The apparatus 2200 may be a wireless communication device, or a wireless communication device may include the apparatus 2200. In some aspects, the apparatus 2200 includes a reception component 2202, a transmission component 2204, and/or a communication manager 2206, which may be in communication with one another (for example, via one or more buses and/or one or more other components). In some aspects, the communication manager 2206 is the communication manager 140 or the communication manager 150 described in connection with FIG. 1. As shown, the apparatus 2200 may communicate with another apparatus 2208, such as a UE or a network node (such as a CU, a DU, an RU, or a base station), using the reception component 2202 and the transmission component 2204.

In some aspects, the apparatus 2200 may be configured to perform one or more operations described herein in connection with FIGS. 8-19. Additionally, or alternatively, the apparatus 2200 may be configured to perform one or more processes described herein, such as process 2000 of FIG. 20, process 2100 of FIG. 21, or a combination thereof. In some aspects, the apparatus 2200 and/or one or more components shown in FIG. 22 may include one or more components of the wireless communication device described in connection with FIG. 2. Additionally, or alternatively, one or more components shown in FIG. 22 may be implemented within one or more components described in connection with FIG. 2. Additionally, or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The reception component 2202 may receive communications, such as reference signals, control information, data communications, or a combination thereof, from the apparatus 2208. The reception component 2202 may provide received communications to one or more other components of the apparatus 2200. In some aspects, the reception component 2202 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 2200. In some aspects, the reception component 2202 may include one or more antennas, a modem, a demodulator, a MIMO detector, a receive processor, a controller/processor, a memory, or a combination thereof, of the wireless communication device described in connection with FIG. 2.

The transmission component 2204 may transmit communications, such as reference signals, control information, data communications, or a combination thereof, to the apparatus 2208. In some aspects, one or more other components of the apparatus 2200 may generate communications and may provide the generated communications to the transmission component 2204 for transmission to the apparatus 2208. In some aspects, the transmission component 2204 may perform signal processing on the generated communications (such as filtering, amplification, modulation, digital-to-analog conversion, multiplexing, interleaving, mapping, or encoding, among other examples), and may transmit the processed signals to the apparatus 2208. In some aspects, the transmission component 2204 may include one or more antennas, a modem, a modulator, a transmit MIMO processor, a transmit processor, a controller/processor, a memory, or a combination thereof, of the wireless communication device described in connection with FIG. 2. In some aspects, the transmission component 2204 may be co-located with the reception component 2202 in a transceiver.

The communication manager 2206 may support operations of the reception component 2202 and/or the transmission component 2204. For example, the communication manager 2206 may receive information associated with configuring reception of communications by the reception component 2202 and/or transmission of communications by the transmission component 2204. Additionally, or alternatively, the communication manager 2206 may generate and/or provide control information to the reception component 2202 and/or the transmission component 2204 to control reception and/or transmission of communications.

The communication manager 2206 may encode one or more information bits into a plurality of polar code sub-block outputs. The communication manager 2206 may identify one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits. The transmission component 2204 may transmit a polar-coded codeword derived from at least the first polar code sub-block output and the second polar code sub-block output.

The communication manager 2206 may identify one or more shaping bit subchannels of a mother code sequence, wherein the one or more shaping bit subchannels are associated with a first polar code sub-block output. The communication manager 2206 may identify one or more information bit subchannels of the mother code sequence. The transmission component 2204 may transmit one or more shaping bits in the one or more shaping bit subchannels and one or more information bits in the one or more information bit subchannels.

The communication manager 2206 may replace one or more candidate shaping bit subchannels with the one or more shaping bit subchannels based at least in part on the first reliability metrics.

The number and arrangement of components shown in FIG. 22 are provided as an example. In practice, there may be additional components, fewer components, different components, or differently arranged components than those shown in FIG. 22. Furthermore, two or more components shown in FIG. 22 may be implemented within a single component, or a single component shown in FIG. 22 may be implemented as multiple, distributed components. Additionally, or alternatively, a set of (one or more) components shown in FIG. 22 may perform one or more functions described as being performed by another set of components shown in FIG. 22.

The following provides an overview of some Aspects of the present disclosure:

Aspect 1: A method of wireless communication performed by a wireless communication device, comprising: encoding one or more information bits into a plurality of polar code sub-block outputs; identifying one or more shaping bits for a first polar code sub-block output of the plurality of polar code sub-block outputs, wherein the first polar code sub-block output is mapped to a first bit level and a second polar code sub-block output of the plurality of the polar code sub-block outputs is mapped to a second bit level, and wherein the second polar code sub-block output is independent from the one or more shaping bits; and transmitting a polar-coded codeword derived from at least the first polar code sub-block output and the second polar code sub-block output.

Aspect 2: The method of Aspect 1, wherein the first bit level is a most significant bit level associated with the polar-coded codeword.

Aspect 3: The method of any of Aspects 1-2, wherein identifying the one or more shaping bits includes: identifying the one or more shaping bits based at least in part on an LLR value.

Aspect 4: The method of any of Aspects 1-3, wherein identifying the one or more shaping bits includes: performing a polar-decoding operation associated with the first polar code sub-block output.

Aspect 5: The method of any of Aspects 1-4, wherein identifying the one or more shaping bits includes: polar-decoding the polar-coded codeword based at least in part on an association of each polar code sub-block output of the plurality of polar code sub-block outputs, other than the first polar code sub-block output, with a punctured node or a shortened node.

Aspect 6: The method of any of Aspects 1-5, wherein the polar-coded codeword is based at least in part on a Gray mapping, and wherein the first polar code sub-block output does not map to any sign bits.

Aspect 7: The method of any of Aspects 1-6, wherein the polar-coded codeword is based at least in part on natural order mapping, and wherein the first polar code sub-block output is mapped to one or more sign bits.

Aspect 8: The method of any of Aspects 1-7, wherein the first polar code sub-block output is associated with a quantity of polarization iterations that is based at least in part on a target subchannel reliability associated with the one or more shaping bits or based at least in part on a target forward error correction performance associated with the one or more shaping bits.

Aspect 9: The method of any of Aspects 1-8, wherein the wireless communication device is a UE.

Aspect 10: The method of any of Aspects 1-8, wherein the wireless communication device is a network node.

Aspect 11: A method of wireless communication performed by a wireless communication device, comprising: identifying one or more shaping bit subchannels of a mother code sequence, wherein the one or more shaping bit subchannels are associated with a first polar code sub-block output; identifying one or more information bit subchannels of the mother code sequence; and transmitting one or more shaping bits in the one or more shaping bit subchannels and one or more information bits in the one or more information bit subchannels.

Aspect 12: The method of Aspect 11, wherein identifying the one or more shaping bit subchannels includes: identifying the one or more shaping bit subchannels based at least in part on first reliability metrics of subchannels associated with at least the first polar code sub-block output and second reliability metrics of subchannels associated with at least a second polar code sub-block output.

Aspect 13: The method of any of Aspects 11-12, wherein identifying the one or more shaping bit subchannels includes: identifying the one or more shaping bit subchannels based at least in part on first reliability metrics of subchannels associated with the first polar code sub-block output independent of any second reliability metric of subchannels associated with any second polar code sub-block output.

Aspect 14: The method of Aspect 13, further comprising: replacing one or more candidate shaping bit subchannels with the one or more shaping bit subchannels based at least in part on the first reliability metrics.

Aspect 15: The method of any of Aspects 11-14, wherein identifying the one or more shaping bit subchannels includes a combination of: identifying the one or more shaping bit subchannels based at least in part on first reliability metrics of subchannels associated with at least the first polar code sub-block output and second reliability metrics of subchannels associated with at least a second polar code sub-block output; and identifying the one or more shaping bit subchannels based at least in part on the first reliability metrics independent of the second reliability metrics.

Aspect 16: The method of any of Aspects 11-15, wherein identifying the one or more shaping bit subchannels includes: recomputing the one or more shaping bit subchannels according to a probability associated with one or more shaped symbols.

Aspect 17: The method of any of Aspects 11-16, wherein the wireless communication device is a UE.

Aspect 18: The method of any of Aspects 11-16, wherein the wireless communication device is a network node.

Aspect 19: An apparatus for wireless communication at a device, comprising a processor; memory coupled with the processor; and instructions stored in the memory and executable by the processor to cause the apparatus to perform the method of one or more of Aspects 1-18.

Aspect 20: A device for wireless communication, comprising a memory and one or more processors coupled to the memory, the one or more processors configured to perform the method of one or more of Aspects 1-18.

Aspect 21: An apparatus for wireless communication, comprising at least one means for performing the method of one or more of Aspects 1-18.

Aspect 22: A non-transitory computer-readable medium storing code for wireless communication, the code comprising instructions executable by a processor to perform the method of one or more of Aspects 1-18.

Aspect 23: A non-transitory computer-readable medium storing a set of instructions for wireless communication, the set of instructions comprising one or more instructions that, when executed by one or more processors of a device, cause the device to perform the method of one or more of Aspects 1-18.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. A wireless communication device for wireless communication, comprising:
one or more memories; and
one or more processors, coupled to the one or more memories, configured to:
identify one or more shaping bit subchannels of a mother code sequence, wherein the one or more shaping bit subchannels are associated with a first polar code sub-block output;
identify one or more information bit subchannels of the mother code sequence; and
transmit one or more shaping bits in the one or more shaping bit subchannels and one or more information bits in the one or more information bit subchannels.

2. The wireless communication device of claim 1, wherein the one or more processors, to identify the one or more shaping bit subchannels, are configured to:
identify the one or more shaping bit subchannels based at least in part on first reliability metrics of subchannels associated with at least the first polar code sub-block output and second reliability metrics of subchannels associated with at least a second polar code sub-block output.

3. The wireless communication device of claim 1, wherein the one or more processors, to identify the one or more shaping bit subchannels, are configured to:
identify the one or more shaping bit subchannels based at least in part on first reliability metrics of subchannels associated with the first polar code sub-block output independent of any second reliability metric of subchannels associated with any second polar code sub-block output.

4. The wireless communication device of claim 3, wherein the one or more processors are further configured to:
replace one or more candidate shaping bit subchannels with the one or more shaping bit subchannels based at least in part on the first reliability metrics.

5. The wireless communication device of claim 1, wherein the one or more processors, to identify the one or more shaping bit subchannels, are configured to perform a combination of:
identify the one or more shaping bit subchannels based at least in part on first reliability metrics of subchannels associated with at least the first polar code sub-block output and second reliability metrics of subchannels associated with at least a second polar code sub-block output; and
identify the one or more shaping bit subchannels based at least in part on the first reliability metrics independent of the second reliability metrics.

6. The wireless communication device of claim 1, wherein the one or more processors, to identify the one or more shaping bit subchannels, are configured to:
recompute the one or more shaping bit subchannels according to a probability associated with one or more shaped symbols.

7. The wireless communication device of claim 1, wherein the wireless communication device is a user equipment (UE).

8. The wireless communication device of claim 1, wherein the wireless communication device is a network node.

9. A method of wireless communication performed by a wireless communication device, comprising:
identifying one or more shaping bit subchannels of a mother code sequence, wherein the one or more shaping bit subchannels are associated with a first polar code sub-block output;
identifying one or more information bit subchannels of the mother code sequence; and
transmitting one or more shaping bits in the one or more shaping bit subchannels and one or more information bits in the one or more information bit subchannels.

10. The method of claim 9, wherein identifying the one or more shaping bit subchannels includes:
identifying the one or more shaping bit subchannels based at least in part on first reliability metrics of subchannels associated with at least the first polar code sub-block output and second reliability metrics of subchannels associated with at least a second polar code sub-block output.

11. The method of claim 9, wherein identifying the one or more shaping bit subchannels includes:
identifying the one or more shaping bit subchannels based at least in part on first reliability metrics of subchannels associated with the first polar code sub-block output independent of any second reliability metric of subchannels associated with any second polar code sub-block output.

12. The method of claim 11, further comprising:
replacing one or more candidate shaping bit subchannels with the one or more shaping bit subchannels based at least in part on the first reliability metrics.

13. The method of claim 9, wherein identifying the one or more shaping bit subchannels includes a combination of:
identifying the one or more shaping bit subchannels based at least in part on first reliability metrics of subchannels associated with at least the first polar code sub-block output and second reliability metrics of subchannels associated with at least a second polar code sub-block output; and
identifying the one or more shaping bit subchannels based at least in part on the first reliability metrics independent of the second reliability metrics.

14. The method of claim 9, wherein identifying the one or more shaping bit subchannels includes:
recomputing the one or more shaping bit subchannels according to a probability associated with one or more shaped symbols.

15. The method of claim 9, wherein the wireless communication device is a user equipment (UE).

16. The method of claim 9, wherein the wireless communication device is a network node.

17. A non-transitory computer-readable medium storing a set of instructions for wireless communication, the set of instructions comprising:
one or more instructions that, when executed by one or more processors of a wireless communication device, cause the wireless communication device to:
identify one or more shaping bit subchannels of a mother code sequence, wherein the one or more shaping bit subchannels are associated with a first polar code sub-block output;
identify one or more information bit subchannels of the mother code sequence; and
transmit one or more shaping bits in the one or more shaping bit subchannels and one or more information bits in the one or more information bit subchannels.

18. The non-transitory computer-readable medium of claim 17, wherein the one or more instructions, that cause the wireless communication device to identify the one or more shaping bit subchannels, cause the wireless communication device to:
identify the one or more shaping bit subchannels based at least in part on first reliability metrics of subchannels associated with at least the first polar code sub-block output and second reliability metrics of subchannels associated with at least a second polar code sub-block output.

19. The non-transitory computer-readable medium of claim 17, wherein the one or more instructions, that cause the wireless communication device to identify the one or more shaping bit subchannels, cause the wireless communication device to:
identify the one or more shaping bit subchannels based at least in part on first reliability metrics of subchannels associated with the first polar code sub-block output independent of any second reliability metric of subchannels associated with any second polar code sub-block output.

20. The non-transitory computer-readable medium of claim 19, wherein the one or more instructions further cause the wireless communication device to:
replace one or more candidate shaping bit subchannels with the one or more shaping bit subchannels based at least in part on the first reliability metrics.

21-30. (canceled)
